(19) United States
(12) Patent Application Publication
(10) Pub. No.: US 2026/0255665 A1
(43) Pub. Date: Aug. 27, 2026

(54) SEMICONDUCTOR DEVICE

(71) Applicant: Samsung Electronics Co., Ltd., Suwon-si (KR)

(72) Inventors: Hyewon Song, Suwon-si (KR); Woohyeon Choi, Suwon-si (KR); Myungil Kang, Suwon-si (KR)

(73) Assignee: Samsung Electronics Co., Ltd., Suwon-si (KR)

(21) Appl. No.: 19/413,258

(22) Filed: Dec. 9, 2025

(30) Foreign Application Priority Data
Feb. 26, 2025 (KR) 10-2025-0025380

(51) Int. Cl. H10D 84/83; H10D 30/00; H10D 30/01; H10D 30/43; H10D 62/10; H10D 62/13; H10D 62/40; H10D 62/83; H10D 64/23; H10D 84/01

(52) U.S. Cl. CPC H10D 84/833; H10D 30/43; H10D 30/502; H10D 62/121; H10D 62/151; H10D 62/405; H10D 62/83; H10D 64/256; H10D 84/8312; H10D 30/014; H10D 30/0191; H10D 84/013; H10D 84/0151

(57) ABSTRACT

A semiconductor device according to embodiments includes a semiconductor device comprising a substrate, a barrier wall on the substrate and extending in a first direction substantially perpendicular to an upper surface of the substrate, a first channel structure and a second channel structure spaced apart from one another across the barrier wall, a gate structure surrounding the first channel structure and the second channel structure, a first source/drain pattern connected to one side of the first channel structure, a second source/drain pattern connected to one side of the second channel structure and spaced apart from the first source/drain pattern across the barrier wall, an insulating liner on at least a portion of a side surface of the barrier wall, wherein the barrier wall includes a first region between the first channel structure and the second channel structure, and a second region between the first source/drain pattern and the second source/drain pattern and wherein an upper surface of the second region is located on a higher level than that of an upper surface of a portion of the insulating liner on a side surface of the second region.

### CROSS-REFERENCE TO RELATED APPLICATIONS

This present application claims priority to and the benefit under 35 U.S.C. § 119(a)-(d) of Korean Patent Application No. 10-2025-0025380, filed on Feb. 26, 2025, in the Korean Intellectual Property Office, the entire disclosure of which is incorporated herein by reference.

### FIELD

The present disclosure relates to a semiconductor device.

### BACKGROUND

A semiconductor is a material that belongs to the intermediate region between conductors and insulators, and is a material that conducts electricity under certain conditions. These semiconductor materials may be used to manufacture various semiconductor devices, such as memory devices. These semiconductor devices may be used in a variety of electronic devices.

As the electronics industry develops, the demands on the characteristics of semiconductor devices are increasing. For example, there is an increasing demand for high reliability, higher speed, and/or multifunctionality in semiconductor devices. To meet these demanding characteristics, structures within semiconductor devices are becoming increasingly complex and integrated. As the size of transistors decreases, coupling may occur between elements, which may reduce the operating speed of the semiconductor device and deteriorate the reliability of the semiconductor device.

### SUMMARY

The embodiments are directed to providing a semiconductor device with improved reliability.

A semiconductor device according to embodiments includes a semiconductor device comprising a substrate, a barrier wall on the substrate and extending in a first direction substantially perpendicular to an upper surface of the substrate, a first channel structure and a second channel structure spaced apart from one another across the barrier wall, a gate structure surrounding the first channel structure and the second channel structure, a first source/drain pattern connected to one side of the first channel structure, a second source/drain pattern connected to one side of the second channel structure and spaced apart from the first source/drain pattern across the barrier wall, an insulating liner on at least a portion of a side surface of the barrier wall, wherein the barrier wall includes a first region between the first channel structure and the second channel structure, and a second region between the first source/drain pattern and the second source/drain pattern and wherein an upper surface of the second region is located on a higher level than that of an upper surface of a portion of the insulating liner on a side surface of the second region.

A semiconductor device according to embodiments includes a substrate, a barrier wall on the substrate and extending in a first direction substantially perpendicular to an upper surface of the substrate, a first channel structure and a second channel structure spaced apart from one another across the barrier wall, a gate structure surrounding the first channel structure and the second channel structure, a first source/drain pattern connected to one side of the first channel structure, a second source/drain pattern connected to one side of the second channel structure and spaced apart from the first source/drain pattern across the barrier wall, an insulating liner on at least a portion of a side surface of the barrier wall, wherein the first source/drain pattern and the second source/drain pattern include a lower region and an upper region on the lower region, wherein the barrier wall includes a first region between the first channel structure and the second channel structure, and a second region between the first source/drain pattern and the second source/drain pattern, and wherein the insulating liner is on side surfaces of the first region and the second region, and an upper surface of a portion of the insulating liner on a side surface of the second region is located on a lower level than that of an upper surface of a portion of the insulating liner on a side surface of the first region.

A semiconductor device according to embodiments includes a substrate, a barrier wall on the substrate and extending in a first direction substantially perpendicular to an upper surface of the substrate, an insulating liner on at least a portion of a side surface of the barrier wall, a first channel structure and a second channel structure spaced apart from one another across the barrier wall in a second direction substantially parallel to the upper surface of the substrate and substantially perpendicular to the first direction, a gate structure surrounding the first channel structure and the second channel structure, a first source/drain pattern connected to one side of the first channel structure and having one side surface in contact with the insulating liner, a second source/drain pattern connected to one side of the second channel structure and spaced apart from the first source/drain pattern across the barrier wall in the second direction and having one side surface in contact with the insulating liner, a power rail located below the substrate, and a lower contact electrode passing through the substrate in the first direction and connecting the power rail to at least one of the first source/drain pattern and the second source/drain pattern, wherein the barrier wall includes a first region between the first channel structure and the second channel structure, and a second region between the first source/drain pattern and the second source/drain pattern, and wherein an upper surface of the second region is located on a higher level than that of an upper surface of a portion of the insulating liner on a side surface of the second region.

A method for manufacturing a semiconductor device according to embodiments comprises forming a barrier wall extending in a first direction substantially perpendicular to an upper surface of the substrate on a substrate, forming an insulating liner surrounding at least a portion of a side surface of the barrier wall, forming a first channel structure and a second channel structure spaced apart from one another across the barrier wall, forming a first source/drain pattern on one side of the first channel structure, forming a second source/drain pattern on one side of the second channel structure, the second source/drain pattern being spaced apart from the first source/drain pattern across the barrier wall, forming a gate structure surrounding the first channel structure and the second channel structure, wherein the barrier wall includes a first region between the first channel structure and the second channel structure, and a second region between the first source/drain pattern and the second source/drain pattern, and the method may further include, after forming the insulating liner and before forming the first source/drain pattern, removing a portion of the insulating liner located on a side surface of the second region of the barrier wall.

The method may further include forming a first insulating pattern on a region from which a portion of the insulating liner has been removed, wherein the first insulating pattern covers a portion of a side surface of the second region of the barrier wall, and a width of the first insulating pattern in a second direction substantially perpendicular to the first direction may be less than or equal to a width of a portion of the insulating liner located on a side surface of the barrier wall in the second direction.

In the method of manufacturing the semiconductor device according to embodiments, an upper surface of the second region may be located on a lower level than that of an upper surface of the first region.

In the method of manufacturing the semiconductor device according to embodiments, when the portion of the insulating liner is removed, a portion of the insulating liner located on a side surface of the first region of the barrier wall may remain unremoved.

In the method of manufacturing the semiconductor device according to embodiments, an upper surface of the portion of the insulating liner located on the side surface of the first region of the barrier wall may be located on the same level as an upper surface of the first region.

In the method of manufacturing a semiconductor device according to embodiments, the substrate may include silicon (Si), and an upper surface of the substrate may have a crystal orientation.

In the method of manufacturing the semiconductor device according to embodiments, forming the first source/drain pattern may include forming a lower region on the substrate and forming an upper region on the lower region, wherein the upper region has a width greater than that of the lower region.

In a method for manufacturing a semiconductor device according to embodiments, a difference between a maximum width of the upper region along the second direction and a maximum width of the lower region along the second direction may be greater than 0 nm and less than or equal to 10 nm.

According to embodiments, the semiconductor device with improved reliability may be provided.

### BRIEF DESCRIPTION OF THE DRAWINGS

FIG. 1 is a plan view showing a semiconductor device according to embodiments.

FIG. 2 is a cross-sectional view taken along line l1-l1′ of FIG. 1.

FIG. 3 is a cross-sectional view taken along line l2-l2′ of FIG. 1.

FIG. 4 is a cross-sectional view taken along line l3-l3′ of FIG. 1.

FIG. 5 is a cross-sectional view taken along line l4-l4′ of FIG. 1.

FIG. 6 is an enlarged cross-sectional view of area A of FIG. 3.

FIG. 7 and FIG. 8 are views for explaining a semiconductor device according to embodiments.

FIG. 9 is a view for explaining a semiconductor device according to embodiments.

FIG. 10 is a view for explaining a semiconductor device according to embodiments.

FIG. 11 is a view for explaining a semiconductor device according to embodiments.

FIG. 12 to FIG. 64 are process cross-sectional views for explaining a method for manufacturing a semiconductor device according to embodiments.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly describe the present disclosure, parts not related to the description are omitted, and throughout the entire specification, the same reference numerals are used to designate the same or similar elements.

In addition, the sizes and thicknesses of the elements shown in the drawings are illustrated schematically for convenience of explanation, and thus the present disclosure is not limited to the drawings as illustrated. In the drawings, the thicknesses of various layers and regions are exaggerated for clarity. And In the drawings, for convenience of explanation, the thicknesses of some layers and regions are exaggerated.

In addition, when a layer, film, region, plate, or the like is described as being “on” another part, it is to be understood that this includes both cases where it is directly on the other part and cases where one or more other layers may be interposed therebetween. Conversely, when apart is described as being “directly on” another part, it is to be understood that no other layer or element is interposed therebetween. In addition, when a part is described as being “on” or “over” a reference part, it may be located either above or below the reference part, and does not necessarily mean that it is positioned upward in the direction opposite to gravity.

Additionally, throughout the specification, whenever a part is said to “include” a component, this does not mean that it excludes other components, but rather that it may include other components, unless otherwise specifically stated.

In addition, throughout the specification, the term “in plan view” refers to a view of a target part as seen from above, and the term “in cross-sectional view” refers to a view of a cross section of the target part taken vertically and viewed from the side.

In the drawings illustrating a semiconductor device according to embodiments, examples of transistors including nanowires or nanosheets, a Multi-Bridge Channel Field Effect Transistor (MBCFET™), and a Fin-type transistor (FinFET) having a channel region with a fin-shaped pattern are shown by way of example only, and the present disclosure is not limited thereto. It is to be understood that some semiconductor devices according to certain embodiments may also include, but are not limited thereto, a tunneling field-effect transistor (tunneling FET), a 3D stack field-effect transistor (3DSFET), and a complementary field-effect transistor (CFET).

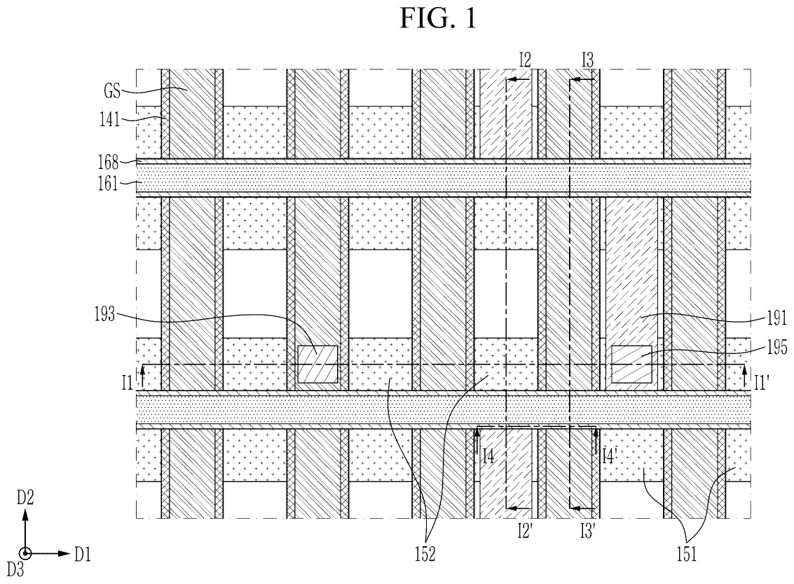

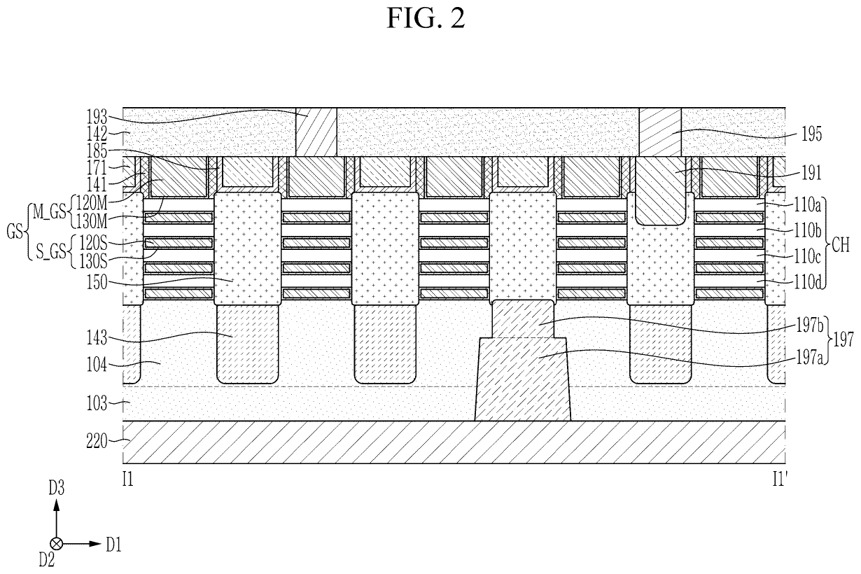

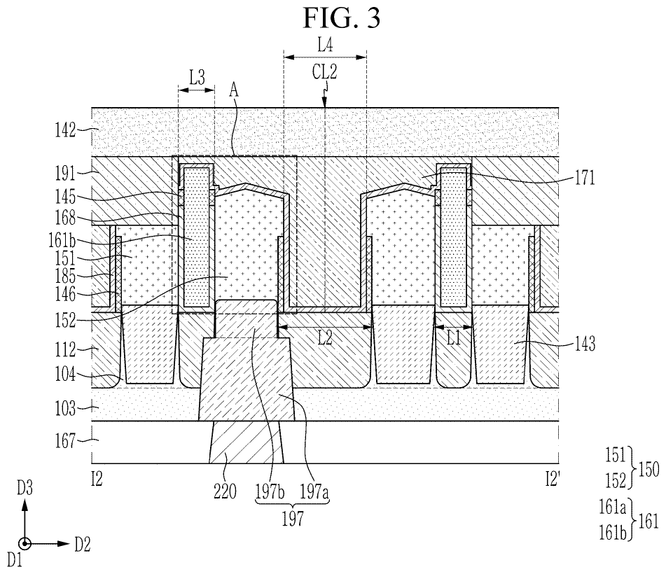

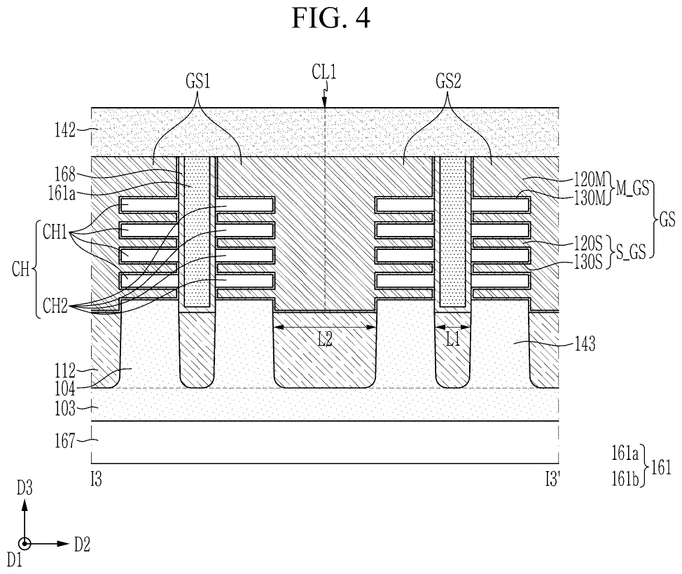

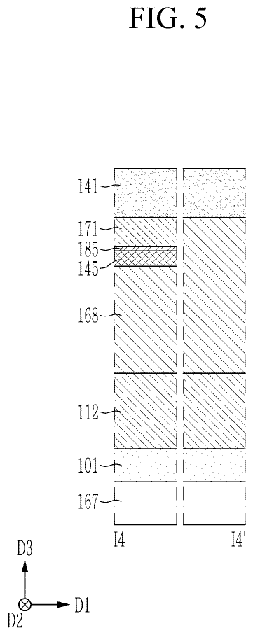

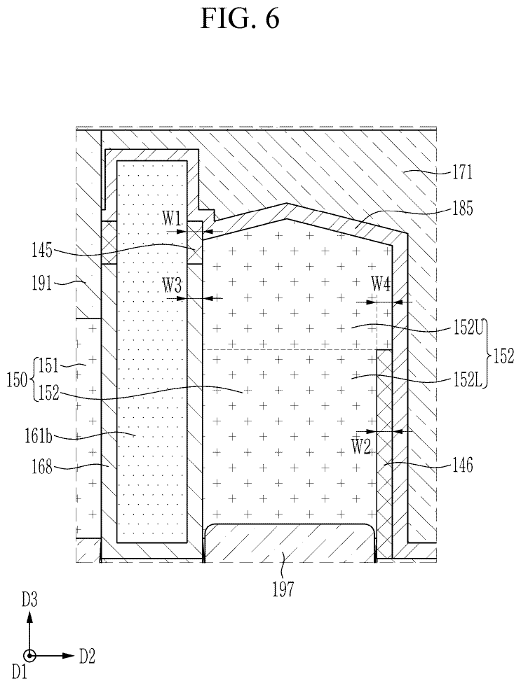

Hereinafter, a semiconductor device according to embodiments will be described with reference to FIG. 1 to FIG. 6. Specifically, FIG. 1 is a plan view illustrating a semiconductor device according to embodiments, FIG. 2 is a cross-sectional view taken along line l1-l1′ of FIG. 1, FIG. 3 is a cross-sectional view taken along line l2-l2′ of FIG. 1, FIG. 4 is a cross-sectional view taken along line l3-l3′ of FIG. 1, FIG. 5 is a cross-sectional view taken along line l4-l4′ of FIG. 1, and FIG. 6 is an enlarged view of region A in FIG. 3.

Referring to FIG. 1 to FIG. 6, a semiconductor device according to embodiments may include a substrate 103, a barrier wall 161 on the substrate 103, channel structures CH spaced apart from one another with the barrier wall 161 interposed therebetween, a gate structure GS surrounding the channel structures CH, source/drain patterns 151, 152 connected to opposite sides of each of the channel structures CH, and an insulating liner 168 positioned on at least a portion of a side surface of the barrier wall 161.

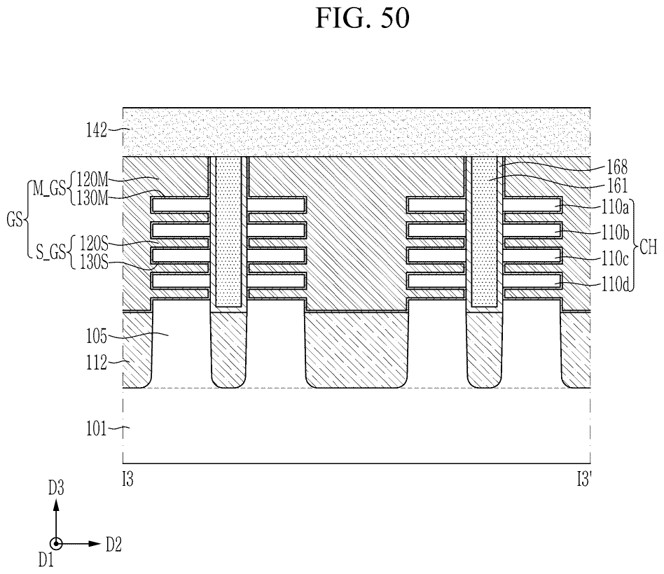

The substrate 103 may include an insulating material. The substrate 103 may include an oxide, a nitride, an oxynitride, or a combination thereof. For example, the substrate 103 may include silicon oxide (SiO2). Although the substrate 103 is illustrated as a single layer, this is for convenience of explanation only and is not intended to limit the disclosure. The substrate 103 may be formed, for example, by filling an etched portion with an insulating material after etching a semiconductor substrate 101 (see FIG. 50), or a lower pattern 105 (see FIG. 50), but is not limited thereto.

A first surface and a second surface of the substrate 103 may be formed as planes substantially parallel to a first direction D1 and a second direction D2 intersecting the first direction D1. For example, the first surface of the substrate 103 may be the upper surface, and the second surface of the substrate 103 may be the lower surface. The upper surface of the substrate 103 is a surface opposite the lower surface of the substrate 103 in the third direction D3. The third direction D3 may be a direction perpendicular to the first direction D1 and the second direction D2. The lower surface of the substrate 103 may be referred to as the back side of the substrate 103. In some embodiments, logic circuitry of a cell region may be formed on an upper surface of the substrate 103.

The semiconductor device according to embodiments may further include a plurality of protruding patterns 104 positioned spaced apart from one another along the second direction D2. The protruding patterns 104 may be extended in the first direction D1. The protruding patterns 104 may be positioned spaced apart from one another along the second direction D2. For example, the protruding patterns 104 may be located in a region in which a PMOS transistor is formed. As another example, the protruding patterns 104 may be located in a region in which an NMOS transistor is formed. For example, in FIG. 4 and FIG. 5, PMOS may be formed on two protruding patterns 104 located on the left, and NMOS may be formed on two protruding patterns 104 located on the right, but the present disclosure is not limited thereto.

A plurality of protruding patterns 104 may be positioned spaced apart from one another in the second direction D2. In embodiments, the distance at which the protruding patterns 104 are spaced from one another may not be constant. Referring to FIG. 1, FIG. 3, and FIG. 4, when no barrier wall 161 is present between the two protruding patterns 104, the two protruding patterns 104 may be spaced apart from one another by a second distance L2. When a barrier wall 161 is present between the two protruding patterns 104, the two protruding patterns 104 may be spaced apart from one another by a first distance L1, which is shorter than the second distance L2. The transistor structures formed on each of the two protruding patterns 104 may be separated from one another by the barrier wall 161. In embodiments, source/drain patterns 150, gate structures GS, and channel structures CH may be positioned on opposite sides of the barrier wall 161. The source/drain patterns 150, gate structures GS and channel structures CH formed on each of the two protruding patterns 104 may be separated from one another by a barrier wall 161. As shown in FIG. 1 to FIG. 6, by providing a barrier wall 161 between the two protruding patterns 104, the size of the semiconductor device according to embodiments may be reduced, and the operating speed of the semiconductor device may be improved.

The semiconductor device according to embodiments may further include an isolation layer 112 located between the protruding patterns 104. The isolation layer 112 may electrically isolate devices that are spaced apart from one another. Specifically, the isolation layer 112 may be located on opposite sides of the protruding patterns 104 extending in the first direction D1. The isolation layer 112 may extend in the first direction D1. A plurality of the isolation layers 112 may be arranged spaced apart from one another along the second direction D2. The plurality of the isolation layers 112 and the plurality of protruding patterns 104 may be arranged alternately along the second direction D2.

In embodiments, the lower surface of the isolation layer 112 may be positioned at substantially the same level as the lower surface of the protruding pattern 104. An upper surface of the isolation layer 112 may be positioned at a lower level than that of an upper surface of the protruding pattern 104. However, it is not limited thereto, and the upper surface of the isolation layer 112 may be positioned at substantially the same level as the upper surface of the protruding pattern 104. The isolation layer 112 may cover at least a portion of an area on opposite sides of the protruding pattern 104.

The isolation layer 112 may include an insulating material. The isolation layer 112 may include an insulating material different from the substrate 103, but is not limited thereto. The isolation layer 112 may include, for example, silicon oxide (SiO₂), silicon nitride (SiNx), silicon oxynitride (SiON), or a combination thereof. However, the present disclosure is not limited thereto, and the isolation layer 112 may include various insulating materials.

The barrier wall 161 may be located on the substrate 103. The barrier wall 161 may be respectively located between two protruding patterns 104 that are adjacent to one another in a second direction D2 on the substrate 103. The barrier wall 161 may be located on at least a portion of the isolation layer 112. Specifically, the barrier wall 161 may be located on a portion of the isolation layer 112 that is positioned between two protruding patterns 104 adjacent to one another in a second direction D2. Referring to FIG. 1, the barrier wall 161 may extend along the first direction D1. A plurality of barrier walls 161 located on the substrate 103 may be spaced apart from one another along the second direction D2. On opposite sides of the barrier wall 161, source/drain patterns 150, channel structures CH, and gate structures GS, which will be described later may be located.

Unlike what is shown in FIG. 3 and FIG. 4, the portion of the isolation layer 112 may not be located under the barrier wall 161. In this case, the barrier wall 161 may be extended further toward the upper surface of the substrate 103 compared to that shown in FIG. 3 and FIG. 4. In this case, the lower surface of the barrier wall 161 may be in contact with the upper surface of the substrate 103. In this case, the barrier wall 161 may include a region overlapping the protruding pattern 104 and the isolation layer 112 in a second direction D2.

The barrier wall 161 may be located between the side surfaces of the channel structures CH, gate structures GS and source/drain patterns 150, which will be described later. Channel structures CH, gate structures GS, and source/drain patterns 150, which are located on the substrate 103, may be spaced apart from one another across the barrier wall 161. Specifically, two channel structures CH may be spaced apart from one another in a second direction D2 with a single barrier wall 161, which extends in a first direction D1, interposed therebetween. Two gate structures GS may be spaced apart from one another in a second direction D2 with a single barrier wall 161, which extends in a first direction D1, interposed therebetween. Two source/drain patterns 151 and 152 may be spaced apart from one another in a second direction D2 with a single barrier wall 161, which extends in a first direction D1, interposed therebetween. Specifically, in a cross-sectional view (e.g., FIG. 3 and FIG. 4), two transistor structures, each including the channel structure CH, the gate structure GS, and the source/drain pattern 150, may be spaced apart from one another on the single substrate 103 with the single barrier wall 161 interposed therebetween.

In embodiments, a distance between two source/drain patterns 150 that are adjacent to one another on opposite sides of a single barrier wall 161 may be smaller than a distance between each of the two source/drain patterns 150 and another source/drain pattern 150 spaced apart in a second direction D2. Specifically, when the barrier wall 161 is located between two source/drain patterns 150, the source/drain patterns 150 may be located spaced apart from one another by a third distance L3. In embodiments, the third distance L3 may be substantially the same as or similar to the first distance L1, but is not limited thereto.

When a barrier wall 161 is not located between the source/drain patterns 150, the source/drain patterns 150 may be located spaced apart from one another by a fourth distance L4 longer than the third distance L3. In embodiments, the fourth distance L4 may be substantially the same as or similar to the second distance L2, but is not limited thereto. For example, the fourth distance L4 may be narrower than the third distance L3 by twice the fourth width W4, which will be described later.

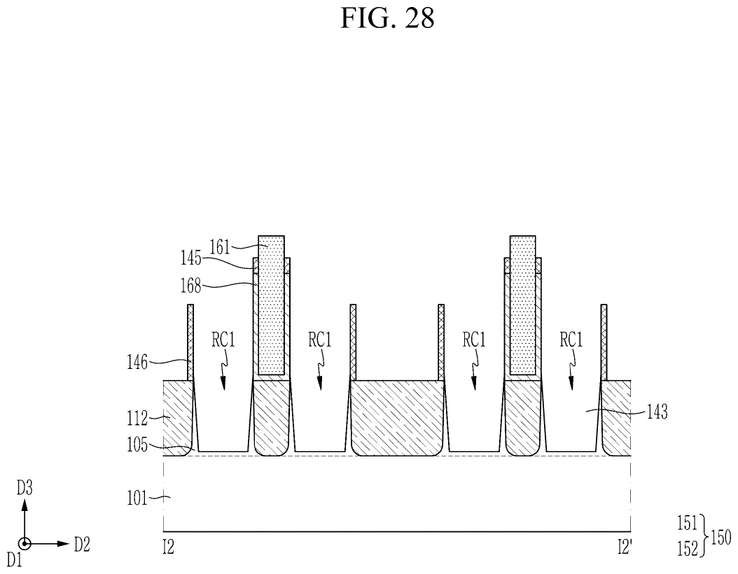

In embodiments, the level at which the upper surface of the barrier wall 161 is positioned may not be constant. Specifically, referring to FIG. 3 to FIG. 5, in embodiments, the barrier wall 161 may include a second region 161b (the region illustrated in the cross-sectional view of FIG. 3), positioned between two source/drain patterns 151, 152 and a first region 161a (the region illustrated in the cross-sectional view of FIG. 4), positioned between two channel structures CH1, CH2. In embodiments, the upper surface of the second region 161b may be positioned at a lower level than that of the upper surface of the first region 161a. This may be due to a process characteristic in which a part of the second region 161b of the barrier wall 161 is etched together with an etching material (etchant, etching gas, etc.) in a process of recessing a part of the substrate or semiconductor layer to form a source/drain pattern 150 (see FIG. 28).

In embodiments, the upper surface of the first region 161a may be in contact with the lower surface of the capping layer 142, which will be described later. The first region 161a may have its upper surface positioned at substantially the same level as the upper surface of the gate structure GS, which will be described later. The lower surface of the first region 161a may be located on a level between the upper surface and the lower surface of the protruding pattern 104, but is not limited thereto.

In embodiments, the upper surface of the second region 161b may be positioned spaced apart from the lower surface of the capping layer 142 in the third direction D3. An interlayer insulating layer 171, which will be described later, may be located between the capping layer 142 and the second region 161b. The lower surface of the second region 161b may be positioned at substantially the same height as the lower surface of the first region 161a, but is not limited thereto.

The barrier wall 161 may include an insulating material. The barrier wall 161 may include, for example, silicon oxide (SiO₂), silicon nitride (SiNx), silicon oxynitride (SiON), or a combination thereof. However, without being limited thereto, the isolation layer 112 may include various insulating materials. In some embodiments, the barrier wall 161 may comprise a low-k material. For example, the barrier wall 161 may include an insulating material having a dielectric constant lower than that of silicon oxide (SiO₂). When the barrier wall 161 includes a low-k material, parasitic capacitance between adjacent transistor structures across the barrier wall 161 may be reduced. In this case, coupling between two adjacent transistor structures may be reduced, thereby improving the reliability of the semiconductor device.

In embodiments, the barrier wall 161 may include an insulating material having a lower dielectric constant than an insulating material included in an insulating liner 168, which will be described later, but is not limited thereto.

An insulating liner 168 may surround at least a portion of the barrier wall 161. The insulating liner 168 may be located on at least a portion of a lower surface and side surface of the barrier wall 161. The insulating liner 168 may be conformally located on the side and bottom surfaces of the barrier wall 161. An insulating liner 168 may be located between the lower surface of the barrier wall 161 and the isolation layer 112.

In embodiments, the level at which the upper surface of the insulating liner 168 is positioned may not be constant. Specifically, referring to FIG. 1, FIG. 3, FIG. 4, and FIG. 5, the upper surface of a portion of the insulating liner 168 on the side surface of the second region 161b of the barrier wall 161 may be positioned at a lower level than that of the upper surface of a portion of the insulating liner 168 on the side surface of the first region 161a of the barrier wall 161.

In the cross-sectional view shown in FIG. 4, the insulating liner 168 may cover the entire side surface of the first region 161a of the barrier wall 161. In embodiments, the upper surface of a portion of the insulating liner 168 on the side surface of the first region 161a may be in contact with the lower surface of the capping layer 142, which will be described later. In embodiments, the upper surface of the portion of the insulating liner 168 on the side of the first region 161a may be positioned at substantially the same level as the upper surface of the barrier wall 161.

In the cross-sectional view shown in FIG. 3, the insulating liner 168 may cover only a portion of the entire side area of the second region 161b of the barrier wall 161. Among the entire region of the barrier wall 161, a portion of the side surface of the upper region may not be covered by the insulating liner 168. In embodiments, the upper surface of a portion of the insulating liner 168 on the side surface of the second region 161b may be spaced apart from the lower surface of the capping layer 142 in the third direction D3, which will be described later. Referring to FIG. 3 and FIG. 5, a first insulating pattern 145, an etch stop layer 185, and an interlayer insulating layer 171, which will be described later, may be located between the upper surface of a portion of an insulating liner 168 on the side surface of the second region 161b and the capping layer 142. In embodiments, the upper surface of the portion of the insulating liner 168 on the side of the second region 161b may be positioned at a lower level than that of the upper surface of the source/drain pattern 150, but is not limited thereto. For example, the upper surface of the portion of the insulating liner 168 on the side surface of the second region 161b may be positioned between the upper surface of the source/drain pattern 150 and the upper surface of the second region 161b of the barrier wall 161.

In the case of a semiconductor device according to embodiments, before forming a first recess RC1 (see FIG. 28), to form the source/drain pattern 150, the insulating liner 168 covering the portion of the upper region of the second region 161b may be trimmed. In this case, as shown in FIG. 3, FIG. 4, and FIG. 5, the insulating liner 168 may not be present on the portion of the side surface of the second region 161b of the barrier wall 161. Accordingly, in the semiconductor device according to embodiments, the upper surface of the portion of the insulating liner 168 located on the side surface of the second region 161b may be positioned at a lower level than that of the upper surface of the portion of the insulating liner 168 located on the side surface of the first region 161a.

The insulating liner 168 may include an insulating material. In embodiments, the insulating liner 168 may include an insulating material different from the insulating material included in the barrier wall 161. The insulating liner 168 may include, for example, at least one of silicon oxide (SiO₂), silicon nitride (SiNx), and silicon oxynitride (SiON), but is not limited thereto. In some embodiments, the insulating liner 168 may include an insulating material having a higher dielectric constant than an insulating material included in the barrier wall 161, but is not limited thereto.

The channel structures CH may be on the first surface of the substrate 103. Referring to FIG. 1 and FIG. 2, the channel structures CH may be arranged spaced apart from one another in the first direction D1 on the substrate 103. Referring to FIG. 1 and FIG. 4, the channel structures CH may be arranged spaced apart from one another in the second direction D2 on the substrate 103. In embodiments, one channel structure CH may include a first channel structure CH1 and a second channel structure CH2. The first channel structure CH1 and the second channel structure CH2 may each be on the protruding pattern 104.

In embodiments, the first channel structure CH1 and the second channel structure CH2 may be spaced apart from one another in the second direction D2 with the barrier wall 161 interposed therebetween. A plurality of channel structures CH, each including the first channel structure CH1 and the second channel structure CH2, may be spaced apart from one another in the second direction D2. The distance at which the plurality of channel structures CH are spaced from one another in the second direction D2 may be greater than the distance between the first channel structure CH1 and the second channel structure CH2 included in each of the plurality of channel structures CH.

Each of the channel structures CH may include a first channel pattern 110a, a second channel pattern 110b, a third channel pattern 110c, and a fourth channel pattern 110d. A plurality of channel patterns 110a, 110b, 110c, 110d may be arranged spaced apart from one another in a third direction D3. Referring to FIG. 4, the first channel structure CH1 located on one side of the barrier wall 161 may include the plurality of channel patterns 110a, 110b, 110c, 110d arranged spaced apart from one another in the third direction D3. The second channel structure CH2 located on the other side of the barrier wall 161 may include the plurality of channel patterns 110a, 110b, 110c, 110d arranged spaced apart from one another in the third direction D3.

For example, each of the plurality of channel patterns 110a, 110b, 110c, 110d may have a sheet shape. Each of the channel patterns 110a, 110b, 110c, 110d may be a nanosheet having a thickness of several nanometers along the third direction D3.

Channel structures CH may provide a path for current to flow between source/drain patterns 150, as described below. Referring to FIG. 2, FIG. 3, and FIG. 4, the channel structure CH may be disposed between the source/drain patterns 150 and may electrically connect the source/drain patterns 150 to one another. The channel structures CH may extend through a portion of the gate structure GS in a direction crossing a direction in which the gate structure GS extends (e.g., the first direction D1). In FIG. 2 and FIG. 4, the first channel structure CH1 and the second channel structure CH2 are illustrated as including four channel patterns 110a, 110b, 110c, 110d spaced apart from one another in the third direction D3, but it is not limited thereto, and the number of stacked channel patterns included in each of the channel structure CH1, CH2 may be variously modified.

The channel structures CH may include a semiconductor material. For example, the channel structures CH may include Group IV semiconductors such as Si or Ge, Group III-V compound semiconductors, Group II-VI compound semiconductors, and the like. In embodiments, the substrate 103 may be located below the channel structure CH.

The channel patterns 110a, 110b, 110c, 110d may have side surfaces in contact with the source/drain pattern 150, which will be described later. Referring to FIG. 2, opposite side surfaces of each of the channel patterns 110a, 110b, 110c, 110d may be in contact with two source/drain patterns 150 respectively located on opposite sides of the channel structure CH.

The channel patterns 110a, 110b, 110c, 110d may have some areas in contact with the main gate insulating layer 130M or the sub-gate insulating layer 130S, which will be described later. Referring to FIG. 4, the upper and lower surfaces of each of the channel patterns 110a, 110b, 110c, 110d may be in contact with the main gate insulating layer 130M or the sub-gate insulating layer 130S. One side surface of each of the channel patterns 110a, 110b, 110c, 110d may be in contact with the main gate insulating layer 130M. In embodiments, the another side surface of each of the channel patterns 110a, 110b, 110c, 110d may be in contact with a portion of the insulating liner 168 located on the side surface of the barrier wall 161.

In embodiments, the plurality of channel structures CH may include different types of semiconductor materials. For example, two channel structures CH spaced apart in the second direction D2 may include different types of semiconductor materials. Specifically, in FIG. 4, with respect to the imaginary center line CL1 between the two channel structures CH, the two channel structures CH1, CH2 located on the left side may include a P-type semiconductor material, and the two channel structures CH1, CH2 located on the right side may include an N-type semiconductor material, but is not limited thereto. For example, the channel structures CH respectively formed on two different substrates 103 may include the same type of semiconductor material.

The gate structure GS may be on the substrate 103. The gate structure GS may extend on the substrate 103 in a direction different from the direction in which the protruding pattern 104 and the barrier wall 161 extend. For example, the gate structure GS may extend in a direction that intersects the direction in which the protruding pattern 104 and the barrier wall 161 extend on the substrate 103(e.g., the second direction D2). The gate structures GS may be arranged spaced apart from one another in the first direction D1. The gate structure GS may include a sub-gate structure S_GS and a main gate structure M_GS. The sub-gate structure S_GS may be on the substrate 103, and the main gate structure M_GS may be on the sub-gate structure S_GS.

Each of the sub-gate structures S_GS may be formed of multiple layers. For example, each of the sub-gate structures S_GS may include a sub-gate electrode 120S and a sub-gate insulating layer 130S. The sub-gate structures S_GS and the channel patterns 110a, 110b, 110c, 110d may be alternately stacked in the third direction D3. In FIG. 2, four sub-gate structures S_GS are illustrated as being arranged spaced apart in the third direction D3, but the number of sub-gate structures S_GS arranged spaced apart is not limited thereto. For example, a gate structure GS may include three sub-gate structures S_GS arranged spaced apart from one another in third direction D3.

A plurality of sub-gate electrodes 120S may be spaced apart from one another on the substrate 103. A plurality of sub-gate electrodes 120S and a plurality of channel patterns 110a, 110b, 110c, 110d may be repeatedly and alternately stacked. At least one of the upper and lower surfaces of the plurality of channel patterns 110a, 110b, 110c, 110d may be covered by a sub-gate electrode 120S. For example, the lower surface of the first channel pattern 110a may be covered by the sub-gate electrode 120S, and the upper surface of the fourth channel pattern 110d may be covered by the sub-gate electrode 120S. The upper and lower surfaces of each of the second channel pattern 110b and the third channel pattern 110c may be covered by the sub-gate electrode 120S.

The sub-gate electrode 120S may include at least one of a metal, a metal alloy, a conductive metal nitride, a metal silicide, a doped semiconductor material, a conductive metal oxide, and a conductive metal oxynitride. The sub-gate electrode 120S may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The conductive metal oxides and conductive metal oxynitrides may include oxidized forms of the aforementioned materials, but are not limited thereto.

The sub-gate insulating layer 130S may be located along the peripheries of a plurality of channel patterns 110a, 110b, 110c, 110d. The sub-gate insulating layer 130S may be interposed between the plurality of channel patterns 110a, 110b, 110c, 110d and the sub-gate electrode 120S. The sub-gate insulating layer 130S may include various insulating materials.

In embodiments, the sub-gate insulating layer 130S is illustrated as a single layer, but is not limited thereto. For example, the sub-gate insulating layer 130S may be formed as a multilayer structure including silicon oxide (SiO₂) and a high-k material. In this case, the high-k material may include a material having a dielectric constant greater than that of silicon oxide (SiO₂), such as hafnium oxide (HfO), aluminum oxide (AlO), or tantalum oxide (TaO).

The main gate structure M_GS may be on the sub-gate structure S_GS and the plurality of channel patterns 110a, 110b, 110c, 110d. The main gate structure M_GS may be on the upper surface of the channel pattern 110a located on the uppermost position among the plurality of channel patterns 110a, 110b, 110c, 110d. Referring to FIG. 3 and FIG. 4, the main gate structure M_GS may also be on the isolation layer 112. The main gate structure M_GS may cover opposite sides of the sub-gate structure S_GS.

The main gate structure M_GS may include a main gate electrode 120M and a main gate insulating layer 130M.

The main gate electrode 120M may be on the sub-gate structure S_GS and the plurality of channel patterns 110a, 110b, 110c, 110d. The main gate electrode 120M may extend in the direction intersecting the substrate 103. At least a portion of the main gate electrode 120M may be on the structure in which the sub-gate electrode 120S and the plurality of channel patterns 110a, 110b, 110c, 110d are alternately stacked. The remaining portion of the main gate electrode 120M may cover the side surface of the structure in which the sub-gate electrode 120S and the plurality of channel patterns 110a, 110b, 110c, 110d are alternately stacked. Each of the four side surfaces of the plurality of channel patterns 110a, 110b, 110c, 110d may be surrounded by the sub-gate electrode 120S and/or the main gate electrode 120M.

The main gate electrode 120M may include the same material as the sub gate electrode 120S. For example, the main gate electrode 120M may include at least one of a metal, a metal alloy, a conductive metal nitride, a metal silicide, a doped semiconductor material, a conductive metal oxide, and a conductive metal oxynitride.

The main gate insulating layer 130M may extend along the side surface of the main gate electrode 120M. The main gate insulating layer 130M may extend along the side surface of the gate spacer 141, which will be described later. The main gate insulating layer 130M may include various insulating materials. The main gate insulating layer 130M may include the same material as the sub-gate insulating layer 130S.

In embodiments, the main gate insulating layer 130M is illustrated as a single layer, but is not limited thereto. For example, the main gate insulating layer 130M may be formed as a multilayer including silicon oxide (SiO₂) and a high-k material. In this case, the high-k material may include a material having a dielectric constant greater than that of silicon oxide (SiO₂), such as hafnium oxide (HfO), aluminum oxide (AIO), or tantalum oxide (TaO).

In some embodiments, the gate structure GS may include different materials in different regions. For example, in the cross-sectional view illustrated in FIG. 4, when different types of transistor structures are respectively formed on the protruding patterns 104 located on the left side and the right side with respect to the imaginary center line CL1 between two channel structures CH, the materials included in the gate electrodes included in the respective transistor structure may be different from one another. For example, in FIG. 4, when a P-type transistor structure is located on the protruding pattern 104 positioned on the left side with respect to the imaginary center line CL1, gate electrodes 120M and 120S included in the first gate electrode structure GS1 may include titanium nitride (TiN), but are not limited thereto. For example, in FIG. 4, when an N-type transistor structure is located on the protruding pattern 104 positioned on the right side with respect to the imaginary center line CL1, gate electrodes 120M and 120S included in a second gate electrode structure GS2 may include titanium aluminum carbide (TiAIC), but are not limited thereto.

In embodiments, a portion of the gate structure GS may be in contact with the insulating liner 168 located on the side surface of the barrier wall 161. Referring to FIG. 4, one side surface of the plurality of sub-gate structures S_GS spaced apart from one another in the third direction D3 may be in contact with the insulating liner 168 located on the side surface of a barrier wall 161. One side surface of the main gate structure M_GS may be in contact with the insulating liner 168 located on the side surface of the barrier wall 161.

The semiconductor device according to embodiments may further include a capping layer 142 and a gate spacer 141.

The gate spacer 141 may be on the side surface of the main gate electrode 120M. The gate spacer 141 may be on the channel structure CH. The gate spacer 141 may not be on the side surface of the sub-gate electrode 120S. The gate spacer 141 may not be on the side surface of each of the channel patterns 110a, 110b, 110c, 110d. The gate spacer 141 may not be disposed between the substrate 103 and the plurality of channel patterns 110a, 110b, 110c, 110d. The gate spacer 141 may not be disposed between the plurality of channel patterns 110a, 110b, 110c, 110d that are adjacent to one another in the third direction D3. Although the gate spacer 141 is illustrated as a single layer for convenience of explanation, it is not limited thereto.

The gate spacer 141 may include, for example, at least one of silicon nitride (SiNx), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. The gate spacer 141 is illustrated as a single layer, but this is only for convenience of explanation and is not limited thereto.

The capping layer 142 may be on the main gate structure M_GS and the gate spacer 141. In embodiments, the capping layer 142 may extend in the first direction D1. The capping layer 142 may also be on the interlayer insulating layer 171, which will be described later.

The capping layer 142 may include, for example, at least one of silicon nitride (SIN), silicon oxynitride (SiON), silicon (Si) carbon nitride SiCN, silicon carbon nitride SIOCN, and combinations thereof. The capping layer 142 may include a material having an etch selectivity with respect to an interlayer insulating layer 171, which will be described later.

The source/drain patterns 150 may be located on the upper surface of the substrate 103. A channel structure CH and a gate structure GS may be located between the source/drain patterns 150. Referring to FIG. 2, a plurality of source/drain patterns 150 and a plurality of channel structures CH may be arranged alternately along the first direction D1.

The source/drain patterns 150 may also be arranged in the second direction D2. Referring to FIG. 1, FIG. 3, and FIG. 4, the plurality of protruding patterns 104 may be arranged spaced apart from one another in the second direction D2, and source/drain patterns 150 may be located on respective protruding patterns 104.

In embodiments, the two source/drain patterns 150 may be spaced apart from one another in the second direction D2 with the barrier wall 161 interposed therebetween. For example, referring to FIG. 3, the first source/drain pattern 151 and the second source/drain pattern 152 on the substrate 103 may be spaced apart from one another in the second direction D2 with the barrier wall 161 interposed therebetween. In embodiments, the first source/drain pattern 151 and the second source/drain pattern 152 may be separated from one another by the barrier wall 161. In embodiments, the insulating liner 168 may be located between a portion of one side surface of the source/drain pattern 150, which faces a side surface of the barrier wall 161, and the barrier wall 161. In embodiments, at least a portion of one side surface of the source/drain pattern 150, which faces the side surface of the barrier wall 161, may be in contact with the insulating liner 168 located on the side surface of the barrier wall 161.

In embodiments, each of the source/drain patterns 150 may include a different type of semiconductor material. For example, referring to FIG. 3, with respect to the imaginary center line CL2, two source/drain patterns 151 and 152 located on the left side may include an N-type semiconductor material, and two source/drain patterns 151 and 152 located on the right side may include a P-type semiconductor material.

For example, referring to FIG. 3, among the first source/drain patterns 151 and the second source/drain patterns 152 located on opposite sides of the barrier wall 161, one may include a P-type semiconductor material and the other may include an N-type semiconductor material. Specifically, the first source/drain patterns 151 may include a P-type semiconductor material, and the second source/drain patterns 152 may include an N-type semiconductor material. However, it is not limited thereto, and both the first source/drain patterns 151 and the second source/drain patterns 152 may include an N-type semiconductor material, or both may include a P-type semiconductor material.

The source/drain patterns 150 may be located on opposite sides of the channel structure CH or the sub-gate structure S_GS. Specifically, referring to FIG. 2, each of the source/drain patterns 150 may be arranged spaced apart in a direction intersecting the direction in which the gate structure GS extends (e.g., a first direction D1), with the channel structure CH and/or the sub-gate structure S_GS interposed therebetween. The source/drain pattern 150 may be in direct contact with the channel structure CH or the sub-gate structure S_GS. The source/drain pattern 150 may be in direct contact with the sub-gate insulating layer 130S of the sub-gate structure S_GS. Among the plurality of sub-gate electrodes 120S spaced apart from one another in a third direction D3, a side surface and a bottom surface of a portion of a region of the source/drain pattern 150, which is located at a level lower than a bottom surface of a lowermost sub-gate electrode 120S, may be in contact with the protruding pattern 104.

Unlike those illustrated in FIG. 1 to FIG. 6, the semiconductor device according to embodiments may further include an inner gate spacer between the source/drain pattern 150 and the sub-gate insulating layer 130S. The inner gate spacer may include at least one of silicon nitride (SiNx), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof.

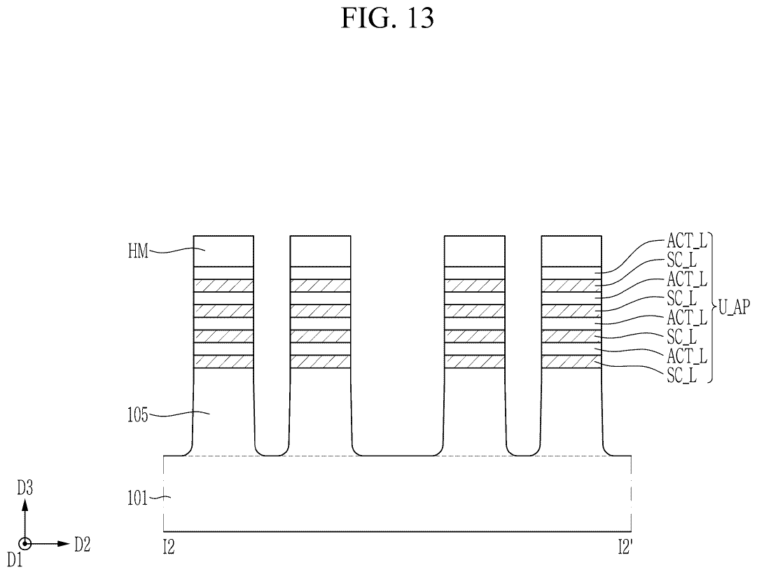

The source/drain pattern 150 may be formed of an epitaxial layer grown by selective epitaxial growth (SEG). The source/drain patterns 150 may be formed by selective epitaxial growth in regions from which at least a portion of a lower pattern 105 (see FIG. 13) positioned on a semiconductor substrate 101 (see FIG. 13) has been removed.

In some embodiments, the source/drain patterns 150 may be grown using a silicon (Si) wafer having a (110) crystal orientation. In this case, the source/drain patterns 150 may be predominantly grown in a vertical direction (e.g., a third direction D3) rather than growing in a lateral direction (e.g., a first direction D1 or a second direction D2). In contrast, when the source/drain patterns 150 are grown on a silicon (Si) wafer having a (100) crystal orientation, they may grow predominantly in a lateral direction rather than in a vertical direction. In some embodiments, since the source/drain patterns 150 grow predominantly in a vertical direction, two source/drain patterns 150 positioned adjacent to opposite sides of the barrier wall 161 may not come into contact with one another during growth, thereby improving the reliability of the semiconductor device.

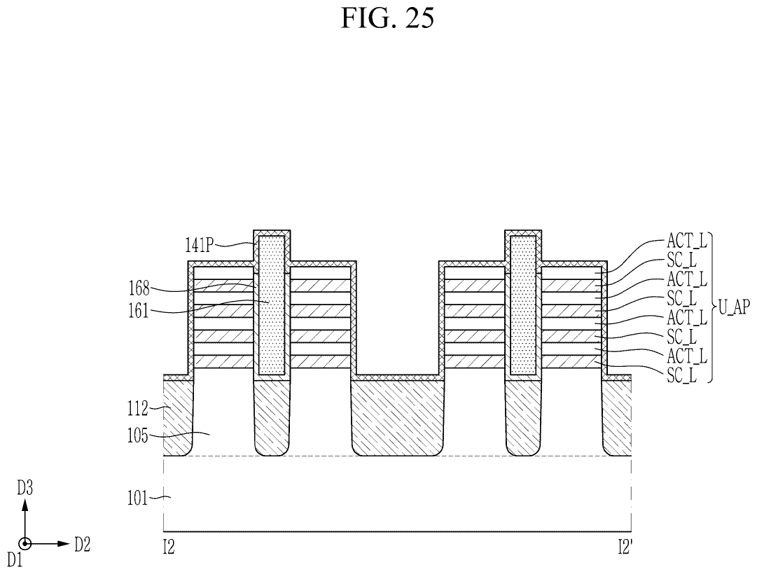

A semiconductor device according to embodiments may further include a first insulating pattern 145 on a portion of one side surface of the source/drain pattern 150 facing the barrier wall 161, and a second insulating pattern 146 positioned on a portion of the other side surface of the source/drain pattern 150. The first insulating pattern 145 and the second insulating pattern 146 may be formed as a result of residual insulating material remaining on the substrate 103 during a process of partially removing a preliminary gate spacer 141P (see FIG. 25).

Referring to FIG. 3, FIG. 5 and FIG. 6, the first insulating pattern 145 may be on the upper surface of the insulating liner 168. Specifically, the first insulating pattern 145 may be on the upper surface of the insulating liner 168 located on the side surface of the second region 161b of the barrier wall 161.

The first insulating pattern 145 may cover one side surface of the source/drain pattern 150 that faces the barrier wall 161, together with the insulating liner 168. The first insulating pattern 145 may be located between the barrier wall 161 and the source/drain pattern 150. The first insulating pattern 145 may also be located between the barrier wall 161 and the etch stop layer 185, which will be described later. In some embodiments, a first width W1 of the first insulating pattern 145 in the second direction D2 may be narrower than or substantially equal to the third width W3 of the portion of the insulating liner 168 located on the side surface of the barrier wall 161.

The second insulating pattern 146 may be on a portion of a side surface opposite to the side surface facing the barrier wall 161 of the source/drain pattern 150. The lower surface of the second insulating pattern 146 may be in contact with the upper surface of the isolation layer 112. The lower surface of the second insulating pattern 146 may be positioned at substantially the same level as the lower surface of the insulating liner 168. The second insulating pattern 146 may extend in the third direction D3. The upper surface of the second insulating pattern 146 may be positioned at a lower level than that of the upper surface of the insulating liner 168 located on the side surface of the second region 161b of the barrier wall 161.

Referring to FIG. 6, in embodiments, the second width W2 of the second insulating pattern 146 along the second direction D2 may be substantially equal to the first width W1 of the first insulating pattern 145 along the second direction D2. This may be due to the process characteristics in which the first insulating pattern 145 and the second insulating pattern 146 are formed simultaneously in the same process (see FIG. 25 and FIG. 28).

In embodiments, the first insulating pattern 145 and the second insulating pattern 146 may include an insulating material. The first insulating pattern 145 and the second insulating pattern 146 may include the same insulating material, but are not limited thereto. In embodiments, the first insulating pattern 145 and the second insulating pattern 146 may include the same insulating material as the gate spacer 141, but are not limited thereto. The first insulating pattern 145 and the second insulating pattern 146 may include at least one of, for example, silicon nitride (SiNx), silicon oxynitride (SiON), silicon oxide (SiO₂), silicon carbonate (SiOCN), silicon boron nitride (SiBN), silicon oxyboron nitride (SiOBN), silicon oxycarbide (SiOC), and combinations thereof. However, the present disclosure is not limited thereto, the first insulating pattern 145 and the second insulating pattern 146 may include various insulating materials.

In embodiments, the source/drain pattern 150 may include two regions having different widths. For example, in the cross-sectional view of FIG. 6, the second source/drain pattern 152 may include a lower region 152L and an upper region 152U positioned above the lower region 152L. Although the second source/drain pattern 152 is described as an example below, the first source/drain pattern 151 may also include regions corresponding to the lower region 152L and the upper region 152U, respectively.

In embodiments, the lower region 152L may overlap the second insulating pattern 146 in the second direction D2. One side surface of the lower region 152L may be in contact with the side surface of the second insulating pattern 146. The other side surface of the lower region 152L, which faces the one side surface, may be in contact with the insulating liner 168. In embodiments, the width of the lower region 152L along the second direction D2 may be constant. In embodiments, the width of the lower region 152L along the second direction D2 may be substantially equal to the gap between the insulating liner 168 and the second insulating pattern 146.

The upper region 152U may be on the lower region 152L. The upper region 152U may not overlap the second insulating pattern 146 in the second direction D2. One side surface of the upper region 152U may be in contact with the insulating liner 168 and the first insulating pattern 145. In embodiments, one side surface of the upper region 152U that is in contact with the insulating liner 168 may be coplanar with one side surface of the lower region 152L that is in contact with the insulating liner 168. In embodiments, the width of the upper region 152U along the second direction D2 may be wider than the width of the lower region 152L along the second direction D2. In embodiments, the difference between the maximum width along the second direction D2 of the upper region 152U and the maximum width along the second direction D2 of the lower region 152L may be greater than 0 and less than or equal to 10 nm.

Referring to FIG. 6, a side surface of the upper region 152U opposite to a side surface that is in contact with the insulating liner 168 may protrude further in the second direction D2, compared to the side surface of the lower region 152L that is in contact with the second insulating pattern 146. In this case, a fourth width W4 of a portion of the upper region 152U that protrudes further in a second direction D2 than one side surface of the lower region 152L may be substantially equal to or less than the second width W2. However, the present disclosure is not limited thereto, and the fourth width W4 may be greater than the second width W2. In embodiments, the fourth width W4 may be greater than 0 nm and less than or equal to about 10 nm.

The cross-sectional shape of the source/drain pattern 150 may vary depending on the crystal orientation of the substrate surface on which the source/drain pattern 150 is grown. In embodiments, the source/drain pattern 150 may be grown on a silicon (Si) substrate having a (110) crystal orientation. Accordingly, the source/drain pattern 150 of the semiconductor device according to embodiments may have a cross-sectional shape different from that of the source/drain pattern 150 grown on a silicon (Si) substrate having a (100) crystal orientation. In a cross-sectional view taken along the second direction D2 and the third direction D3, the upper region 152U may include a region having a uniform width in the second direction D2 and a region having a non-uniform width in the second direction D2. Referring to FIG. 6, the upper region 152U may include two side surfaces extending substantially parallel to one another along the third direction D3 and facing one another. The upper region 152U may include a region in which a width in the second direction D2 gradually decreases as the region becomes farther from the upper surface of the substrate 103. In embodiments, the upper region 152U may have a cross-sectional shape in which a width in the second direction D2 is constant up to a certain point and then gradually decreases as the region becomes farther from the substrate 103.

In embodiments, an upper surface of the upper region 152U may have a triangular cross-sectional shape in which the central portion protrudes sharply toward the third direction D3. In embodiments, the upper surface of the upper region 152U may have a triangular cross-sectional shape in which the width in the second direction D2 gradually decreases as the upper surface becomes farther from the substrate 103.

In embodiments, a highest point of an upper surface of the source/drain pattern 150 may be positioned at a higher level than that of an upper surface of the channel structure CH. Referring to FIG. 2, the upper surface of the source/drain pattern 150 may be positioned at a higher level than that of the upper surface of the uppermost channel pattern 110a among the channel patterns 110a, 110b, 110c, and 110d included in the channel structure CH.

The source/drain pattern 150 may include a semiconductor material. The source/drain pattern 150 may include, for example, silicon (Si) or germanium (Ge). Additionally, the source/drain pattern 150 may include a binary compound or a ternary compound including at least two or more of, for example, carbon (C), silicon (Si), germanium (Ge), and tin (Sn). For example, the source/drain pattern 150 may include silicon (Si), silicon germanium (SiGe), germanium (Ge), silicon carbide (SIC), and the like, but it is not limited thereto.

The semiconductor device according to embodiments may further include a dummy semiconductor pattern 143 under the source/drain pattern 150. The dummy semiconductor pattern 143 may be configured to connect the source/drain pattern 150 to the lower contact electrode 197, which will be described later. Unlike those illustrated in FIG. 2 to FIG. 6, the semiconductor device according to embodiments may not include the dummy semiconductor pattern 143. For example, the dummy semiconductor pattern 143 may be formed only under the source/drain patterns 150 to be connected to the lower contact electrode 197, and may not be formed under the source/drain patterns 150 that are not to be connected to the lower contact electrodes 197.

Referring to FIG. 2, the dummy semiconductor pattern 143 may extend into the interior of the protruding pattern 104 in a direction toward the upper surface of the substrate 103. The lower surface of the dummy semiconductor pattern 143 may be positioned between the level of the upper surface of the substrate 103 and the level of the lower surface of the protruding pattern 104. The upper surface of the dummy semiconductor pattern 143 may be in contact with the lower surface of the source/drain pattern 150. Referring to FIG. 2 and FIG. 3, the side surface and bottom surface of the dummy semiconductor pattern 143 may be covered by the protruding pattern 104.

The dummy semiconductor pattern 143 may include a semiconductor material. In embodiments, the dummy semiconductor pattern 143 may include the same material as the source/drain pattern 150. For example, the dummy semiconductor pattern 143 may include silicon germanium (SiGe). In this case, the germanium (Ge) concentration of the dummy semiconductor pattern 143 may be different from the germanium (Ge) concentration of the source/drain pattern 150. For example, the germanium (Ge) concentration of the dummy semiconductor pattern 143 may be higher than the germanium (Ge) concentration of the source/drain pattern 150.

The semiconductor device according to embodiments may further include an etch stop layer 185. The etch stop layer 185 may cover at least a portion of the upper surface and side surface of the source/drain pattern 150. The etch stop layer 185 may be located on least a portion of the upper surface and side surface of the source/drain pattern 150. Referring to FIG. 6, the etch stop layer 185 may cover the upper surface and side surface of the upper region 152U. The etch stop layer 185 may cover the side surface of the second insulating pattern 146 located on the side surface of the lower region 152L. The etch stop layer 185 may cover a portion of the upper surface and side surface of the second region 161b of the barrier wall 161. Specifically, the etch stop layer 185 may cover the remaining area of the entire side surface of the second region 161b that is not covered by the insulating liner 168 and the first insulating pattern 145. The etch stop layer 185 may also be located on the upper surface of the first insulating pattern 145.

The etch stop layer 185 may include an insulating material. The etch stop layer 185 may include, for example, at least one of silicon nitride (SIN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. The etch stop layer 185 is illustrated as a single layer, but it is only for convenience of explanation and is not limited thereto.

Unlike those shown in FIG. 1 to FIG. 6, the etch stop layer 185 may be omitted. In this case, the upper surface and side surface of the source/drain pattern 150 may be covered by an interlayer insulating layer 171, which will be described later.

The semiconductor device according to embodiments may further include an interlayer insulating layer 171 on the isolation layer 112 and on the upper surface and side surface of the source/drain pattern 150. In embodiments, an etch stop layer 185 may be interposed between the interlayer insulating layer 171 and the isolation layer 112.

The interlayer insulating layer 171 may be on the etch stop layer 185. In embodiments, the interlayer insulating layer 171 may be on the side surface of the source/drain pattern 150. The interlayer insulating layer 171 may cover the side surface of the source/drain pattern 150.

The interlayer insulation layer 171 may include an insulating material. The interlayer insulating layer 171 may include, for example, at least one of silicon nitride (SIN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. The interlayer insulating layer 171 is illustrated as a single layer, but this is only for convenience of explanation and is not limited thereto.

The semiconductor device according to embodiments may further include a first upper contact electrode 191. The first upper contact electrode 191 may be on the source/drain pattern 150. The first upper contact electrode 191 may extend into the interior of the source/drain pattern 150 along the third direction D3. The first upper contact electrode 191 may be between two main gate structures 120M spaced apart from one another in the first direction D1. Referring to FIG. 2, an etch stop layer 185 may further be located between the first upper contact electrode 191 and the gate spacer 141.

In the cross-sectional view of FIG. 3, a portion of one side surface of the first upper contact electrode 191 may be in contact with the insulating liner 168 and the first insulating pattern 145. The remaining portion of one side surface of the first upper contact electrode 191 may be covered by an interlayer insulating layer 171.

Unlike that shown in FIG. 2, the width of the first upper contact electrode 191 in the horizontal direction may not be constant. For example, the first upper contact electrode 191 may have a tapered side surface where the width of the lower portion becomes narrower than the width of the upper portion according to the aspect ratio. For example, a width of the first upper contact electrode 191 in a horizontal direction may gradually decrease toward an upper surface of the source/drain pattern 150. In this case, at least a portion of the side surface of the first upper contact electrode 191 may not be in contact with the etch stop layer 185. In embodiments, the upper surface of the first upper contact electrode 191 may be located on the same plane as the upper surface of the gate structure GS or the upper surface of the first region 161a of the barrier wall 161.

Referring to FIG. 2 and FIG. 3, the first upper contact electrode 191 may be positioned to recess into the source/drain pattern 150 to a predetermined depth. For example, the first upper contact electrode 191 may penetrate a portion of the etch stop layer 185 on the upper surface of the source/drain pattern 150 and extend into the interior of the source/drain pattern 150 by the predetermined depth. Although not shown in FIG. 1 to FIG. 6, the semiconductor device according to embodiments may further include a silicide layer between the first upper contact electrode 191 and the source/drain pattern 150. When the semiconductor device according to embodiments does not include the silicide layer, a portion of the side surface and the lower surface of the first upper contact electrode 191 may be in contact with the source/drain pattern 150, as illustrated in FIG. 2.

The semiconductor device according to embodiments may further include a second upper contact electrode 193 on the gate structure GS. The second upper contact electrode 193 may penetrate a portion of the capping layer 142. The lower surface of the second upper contact electrode 193 may be in contact with the upper surface of the main gate electrode 120M.

The semiconductor device according to embodiments may further include an upper contact via 195 on the first upper contact electrode 191. The upper contact via 195 may penetrate a portion of the capping layer 142. The lower surface of the upper contact via 195 may be in contact with the upper surface of the first upper contact electrode 191. The upper contact via 195 may be connected to the source/drain pattern 150 through the first upper contact electrode 191.

The first upper contact electrode 191, the second upper contact electrode 193, and the upper contact via 195 may include a conductive material. For example, the first upper contact electrode 191, the second upper contact electrode 193, and the upper contact via 195 may include at least one of a metal, a metal alloy, a conductive metal nitride, a metal silicide, a doped semiconductor material, a conductive metal oxide, and a conductive metal nitride.

The semiconductor device according to embodiments may further include a lower contact electrode 197 connected to a lower portion of at least one of the source/drain patterns 150. The lower contact electrode 197 may be connected to the source/drain patterns 150. The lower contact electrode 197 is connected to the source/drain pattern 150 and may provide power or an electrical signal to the source/drain pattern 150. Referring to FIG. 1 and FIG. 2, the lower contact electrode 197 may be connected to the lower portion of the source/drain patterns 150. Although not shown in FIG. 1 and FIG. 2, the semiconductor device according to embodiments may further include a silicide layer located along the interface of the lower contact electrode 197 and the source/drain pattern 150.

In embodiments, the lower contact electrode 197 may be located inside the substrate 103 and the protruding pattern 104. The lower contact electrode 197 may extend a predetermined depth into the substrate 103 and the protruding pattern 104 along the third direction D3. In embodiments, the lower contact electrode 197 may include a lower region 197a and an upper region 197b on the lower region 197a. In embodiments, the width along the horizontal direction (e.g., the first direction D1 or the second direction D2) of the upper region 197b may be narrower than the width along the horizontal direction of the lower region 197a.

The lower surface of the lower contact electrode 197 may be located on the same plane as the lower surface of the substrate 103. The lower contact electrode 197 may have a side surface in contact with the substrate 103 and the protruding pattern 104. A portion of the side surface of the lower contact electrode 197 may be in contact with the isolation layer 112.

The lower contact electrode 197 may include a conductive material. For example, the lower contact electrode 197 may include at least one of a metal, a metal alloy, a conductive metal nitride, a metal silicide, a doped semiconductor material, a conductive metal oxide, and a conductive metal nitride.

The semiconductor device according to embodiments may further include a power rail 220 located below the substrate 103. The power rail 220 may supply power to a semiconductor device according to embodiments. The power rail 220 may extend in a direction intersecting the direction in which the gate structure GS extends, but is not limited thereto. For example, referring to FIG. 2, the power rail 220 may extend along the first direction D1. Unlike those illustrated in FIG. 1 to FIG. 6, the semiconductor device according to embodiments may include a plurality of power rails 220 extending along the first direction D1. A plurality of power rails 220 may be spaced apart from one another in the second direction D2. Unlike that shown in FIG. 2, the power rail 220 may extend in a direction parallel to the direction in which the gate structure GS extends (e.g., in the second direction D2).

In embodiments, the power rail 220 may be connected to an external power source. For example, the power rail 220 may be connected to an external input power source to provide power to a semiconductor device according to embodiments. For example, the power rail 220 may be connected to ground.

The power rail 220 is connected to the lower contact electrode 197 and may provide power to at least one of the source/drain patterns 150. Specifically, in FIG. 3, the power rail 220 may be connected to the second source/drain pattern 152 through the lower contact electrode 197.

The power rail 220 may include a conductive material. For example, the power rail 220 may include at least one of a metal, a metal alloy, a conductive metal nitride, a metal silicide, a doped semiconductor material, a conductive metal oxide, and a conductive metal nitride.

The semiconductor device according to embodiments may further include a lower insulating layer 167 located below the lower surface of the substrate 103. The lower insulating layer 167 may surround the side surface of the power rail 220. The lower insulating layer 167 may electrically isolate the power rail 220 from other power rails 220.

The lower insulating layer 167 may include an insulating material. The lower insulating layer 167 may include, for example, at least one of silicon nitride (SiNx), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof.

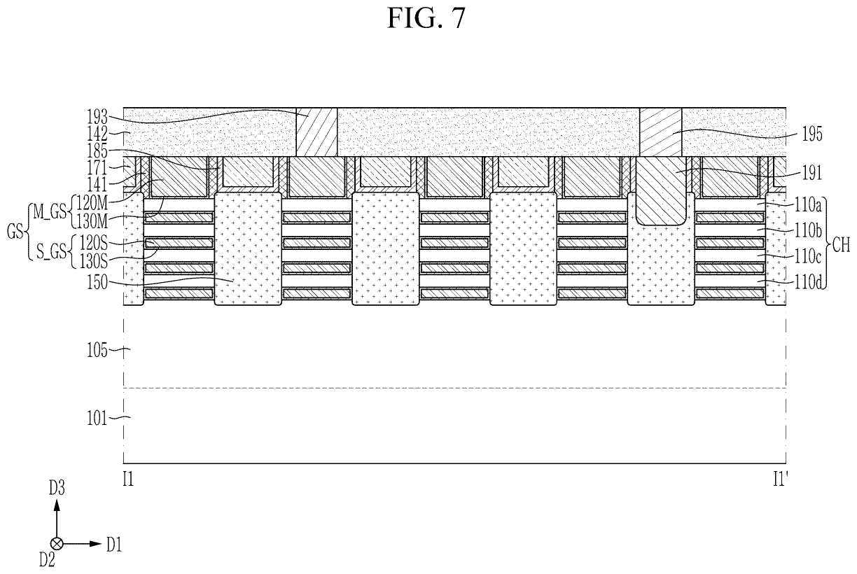

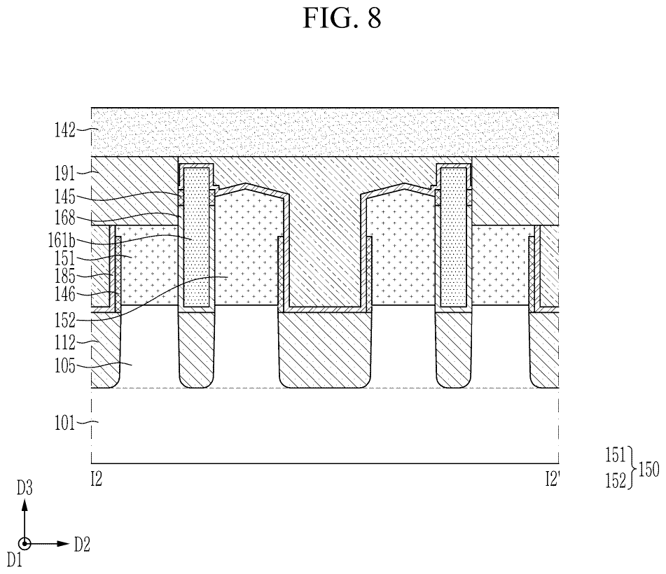

FIG. 7 and FIG. 8 are drawings for explaining a semiconductor device according to embodiments. Since the semiconductor device shown in FIG. 7 and FIG. 8 includes many of the same features as those of the foregoing embodiments, the following description will focus primarily on the differences from the foregoing embodiments. FIG. 7 may correspond to a cross-sectional view taken along line l1-l1′ of FIG. 1. FIG. 8 may correspond to a cross-sectional view taken along line l2-l2′ of FIG. 1.

The semiconductor device according to embodiments may not include a power rail 220 located below the substrate 103 (see FIG. 2 and FIG. 3), as illustrated in FIG. 2 and FIG. 3. In other words, in the semiconductor device described with reference to FIG. 1 to FIG. 6, power rails 220 are located below the substrate 103 (see FIG. 2 and FIG. 3), and power may be supplied through the power rails. However, in the semiconductor device according to embodiments, electrical signals including power and voltage may be supplied through the first upper contact electrode 191 located on the semiconductor substrate 101.

A semiconductor device according to embodiments may further include a semiconductor substrate 101 and a lower pattern 105 on the semiconductor substrate 101. The semiconductor substrate 101 may include a semiconductor material. In embodiments, the semiconductor substrate 101 may be a silicon (Si) wafer having a (110) crystal orientation. In embodiments, as the source/drain patterns 150 are grown on a silicon (Si) wafer having a (110) crystal orientation, the source/drain patterns 150 may grow predominantly in the vertical direction rather than growing in the horizontal direction. The specific shape of the source/drain pattern 150 is the same as that described with reference to FIG. 1 to FIG. 5, so a detailed description thereof is omitted.

The lower pattern 105 may be formed by etching a portion of the semiconductor substrate 101 or by epitaxial growth on the semiconductor substrate 101. According to embodiments, the semiconductor device may not include the dummy semiconductor pattern 143 and the lower contact electrode 197 described with reference to FIG. 1 to FIG. 6.

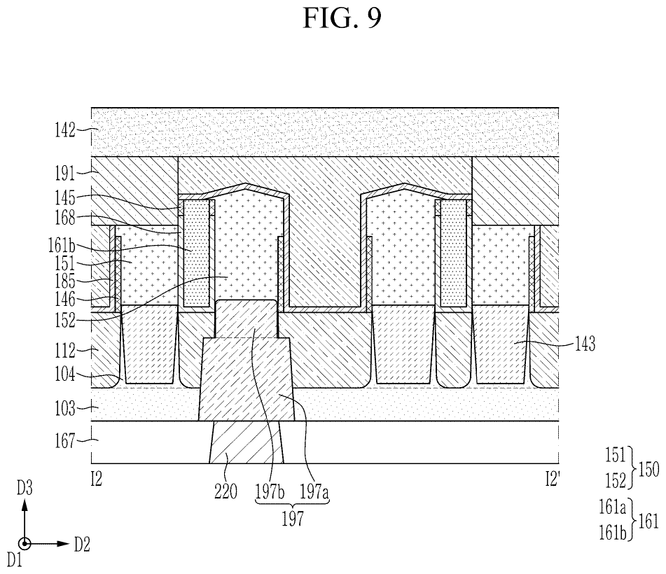

FIG. 9 is a drawing for explaining a semiconductor device according to embodiments. Since the semiconductor device shown in FIG. 9 includes many of the same features as those of the foregoing embodiments, the following description will focus on differences from the foregoing embodiments. FIG. 9 may correspond to a cross-sectional view taken along line l2-l2′ of FIG. 1. The semiconductor device illustrated in FIG. 9 may have a height of the barrier wall 161 that differs compared to the foregoing embodiments.

Referring to FIG. 9, the upper surface of the second region 161b of the barrier wall 161 may be positioned at a lower level than that of the upper surface of the source/drain pattern 150. In embodiments, the upper surface of the second region 161b may be positioned at substantially the same level as the upper surface of the first insulating pattern 145.

In embodiments, a portion of the side surface of the second region 161b may be covered by an insulating liner 168, and the remaining portion of the side surface of the second region 161b may be covered by a first insulating pattern 145. The side surface of the second region 161b may contact the insulating liner 168 and the first insulating pattern 145.

In embodiments, the upper surface of the second region 161b may be covered by an etch stop layer 185. The upper surface of the second region 161b may be in contact with the etch stop layer 185. In embodiments, the side surface of the second region 161b may not be in contact with the etch stop layer 185.

Referring to FIG. 9, at least a portion of the upper surface of the first insulating pattern 145 may be covered by the source/drain pattern 150. A portion of the upper surface of the second region 161b may also be covered by the source/drain pattern 150. However, even in this case, the upper surface of the second region 161b may not be completely covered by the source/drain pattern 150.

In the manufacturing process of the semiconductor device according to embodiments, the source/drain pattern 150 may be grown on a substrate having a (110) crystal orientation. In this case, during the process of forming the source/drain pattern 150, the source/drain pattern 150 may prepredominantly grow in the vertical direction, and lateral growth may be limited. Accordingly, in embodiments, even when the upper surface of the barrier wall 161 is positioned at a lower level than that of the upper surface of the source/drain pattern 150, the source/drain patterns 151, 152 located on both sides of the barrier wall 161 may not contact one another as they grow, thereby improving the reliability of the semiconductor device.

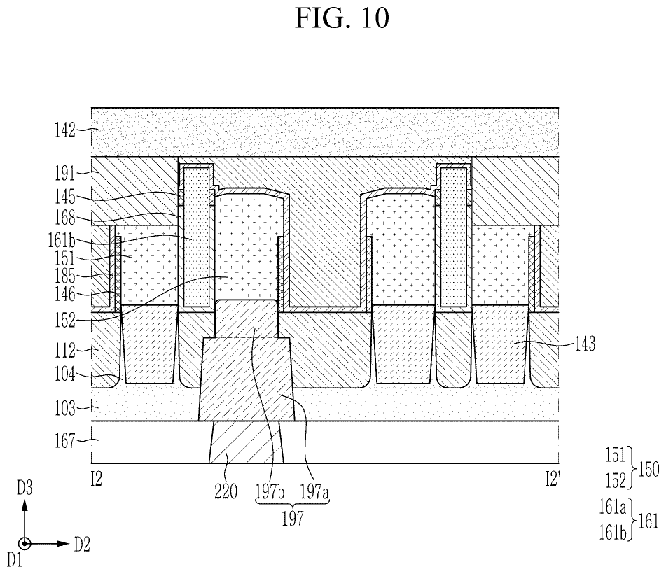

FIG. 10 is a drawing for explaining a semiconductor device according to embodiments. Since the semiconductor device shown in FIG. 10 includes many of the same features as those of the foregoing embodiments, the following description will focus on differences from the foregoing embodiments. FIG. 10 may correspond to a cross-sectional view taken along line l2-l2′ of FIG. 1. The semiconductor device illustrated in FIG. 10 may have a specific shape of the source/drain pattern 150 that differs in part from the foregoing embodiments.

Even if the source/drain pattern 150 is grown on a substrate having the same crystal orientation, its specific shape may vary depending on the process conditions under which the source/drain pattern 150 is grown. For example, the specific shape of the source/drain pattern 150 may vary depending on the time and temperature at which the source/drain pattern 150 is grown, or the type or amount of gas injected into the chamber.

In embodiments, the source/drain pattern 150 may be grown on a silicon substrate having a (110) crystal orientation. Referring to FIG. 10, in embodiments, the upper surface of the source/drain pattern 150 may include a flat portion. Specifically, in embodiments, the upper surface of the source/drain pattern 150 may include a tapered region and a flat region with respect to the upper surface of the substrate 103. In a cross-sectional view along the second direction D2 and the third direction D3, the source/drain pattern 150 may include a region having a constant width and a region in which a width in the second direction D2 gradually decreases as it becomes farther from an upper surface of the substrate 103. In embodiments illustrated in FIG. 2, the center portion of the upper surface of the source/drain pattern 150 protrudes sharply toward the third direction D3, whereas in the semiconductor device according to embodiments illustrated in FIG. 10, the center portion of the upper surface of the source/drain pattern 150 may be flat. Accordingly, in the cross-section along the second direction D2 and the third direction D3, the upper region of the source/drain pattern 150 may have a trapezoidal shape.

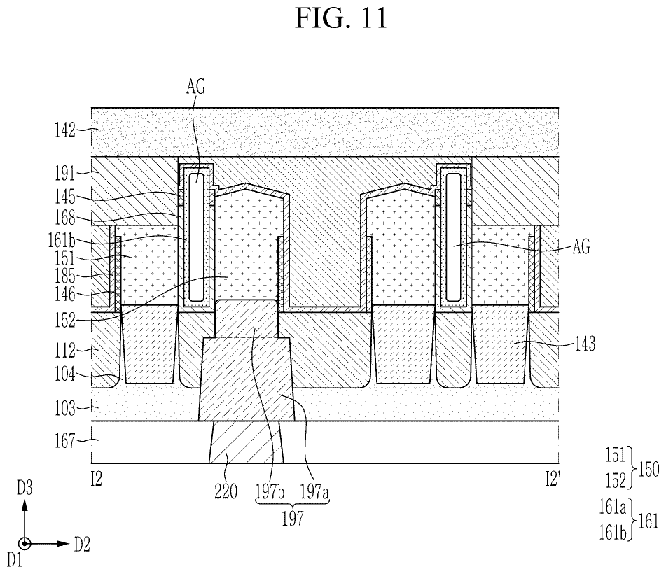

FIG. 11 is a drawing for explaining a semiconductor device according to embodiments. Since the semiconductor device shown in FIG. 11 includes many of the same features as those of the foregoing embodiments, the following description will focus on differences from the foregoing embodiments. FIG. 11 may correspond to a cross-sectional view taken along line l2-l2′ of FIG. 1. The semiconductor device illustrated in FIG. 11 may differ in part from the foregoing embodiments in that it includes an air gap AG.

Referring to FIG. 11, the semiconductor device according to embodiments may further include an air gap AG located inside the barrier wall 161. In embodiments, an air gap AG may be formed inside the barrier wall 161 during the process of forming the barrier wall 161. In FIG. 11, the air gap AG is illustrated as being formed in a rectangular shape with rounded corners, but the specific shape of the air gap AG is not limited thereto. The air gap AG may refer to an empty space located inside a film, or an empty space located between one film and another film. For example, the air gap AG may include air or a gas used in the manufacturing process of the semiconductor device.

In embodiments, the air gap AG may have a lower dielectric constant compared to the insulating material contained in the surrounding insulating layers and insulating patterns. For example, the air gap AG may have a lower dielectric constant compared to the barrier wall 161, the insulating liner 168, the first insulating pattern 145, and the interlayer insulating layer 171. For example, the air gap AG may be filled with air, and the dielectric constant of the air may be approximately 1. The semiconductor device according to embodiments may reduce internal parasitic capacitance by including an air gap AG inside the barrier wall 161, thereby improving electrical characteristics of the semiconductor device.

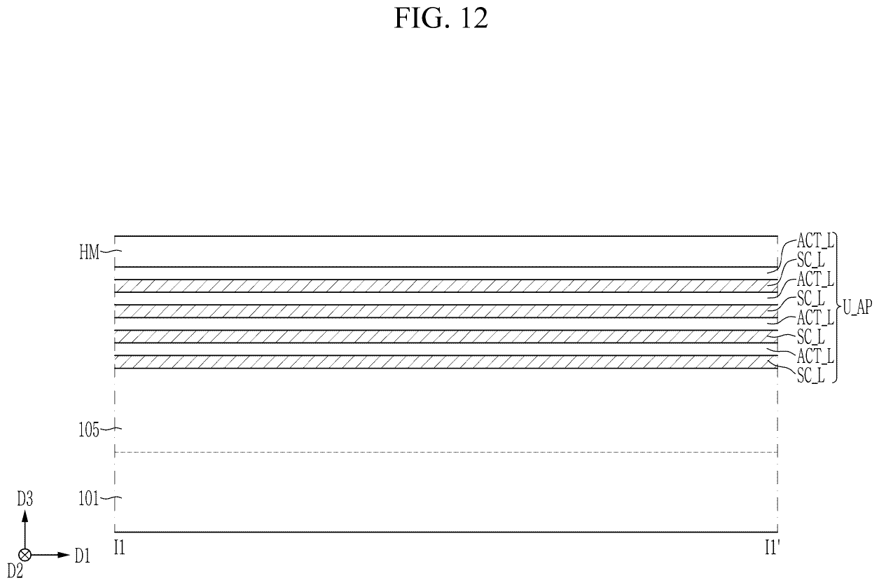

FIGS. 12 to 64 are process cross-sectional views for explaining a method for manufacturing a semiconductor device according to embodiments.

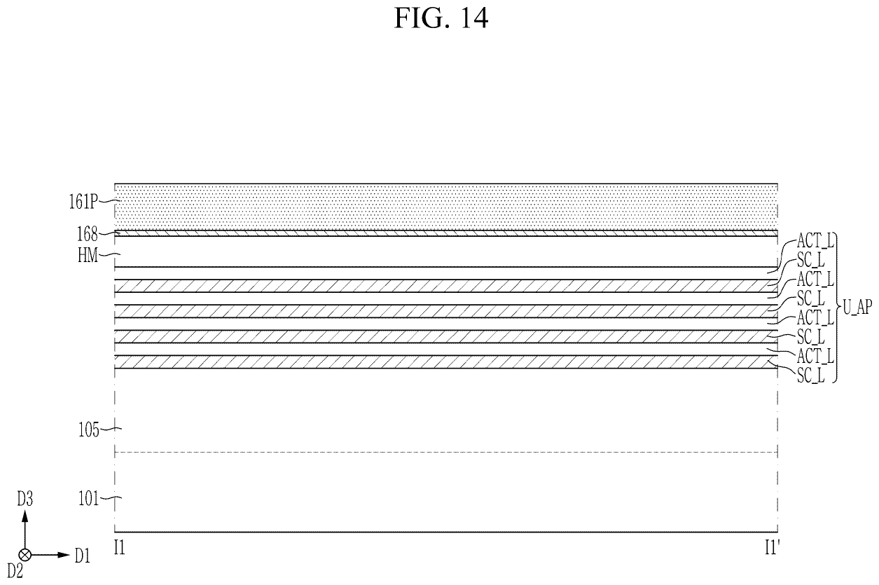

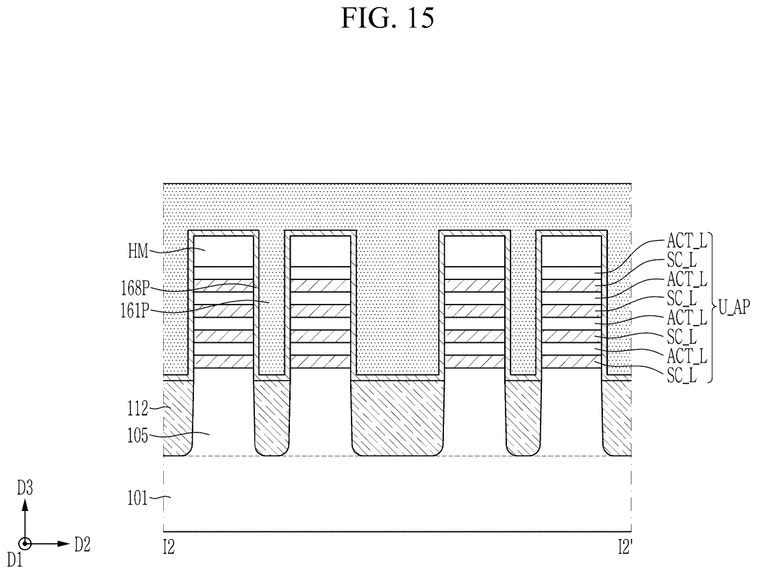

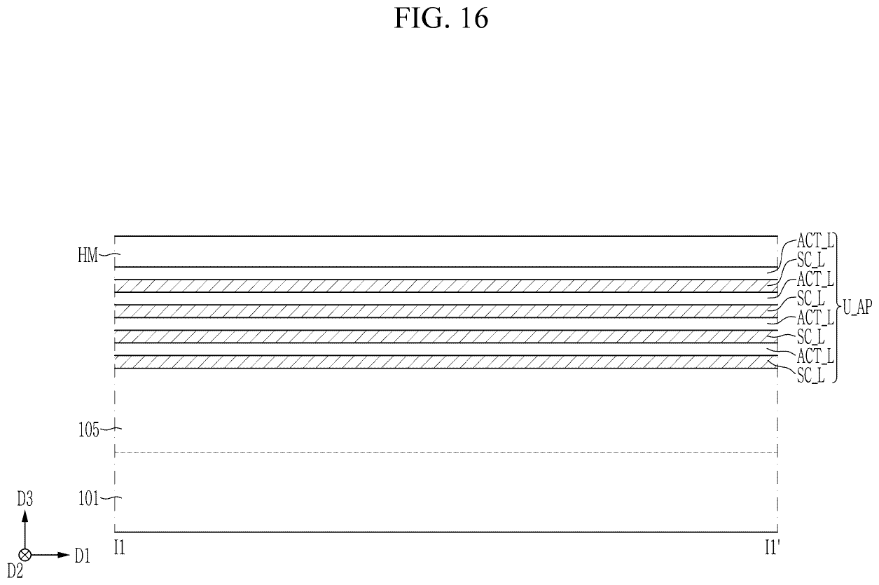

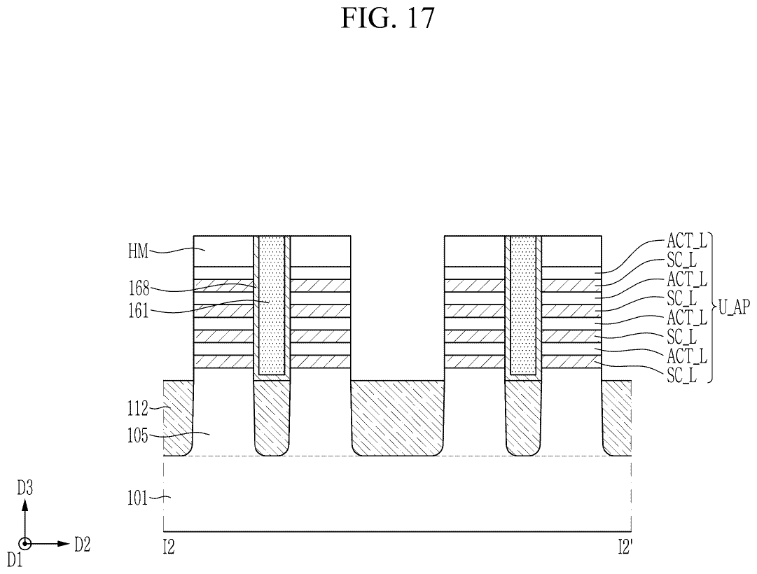

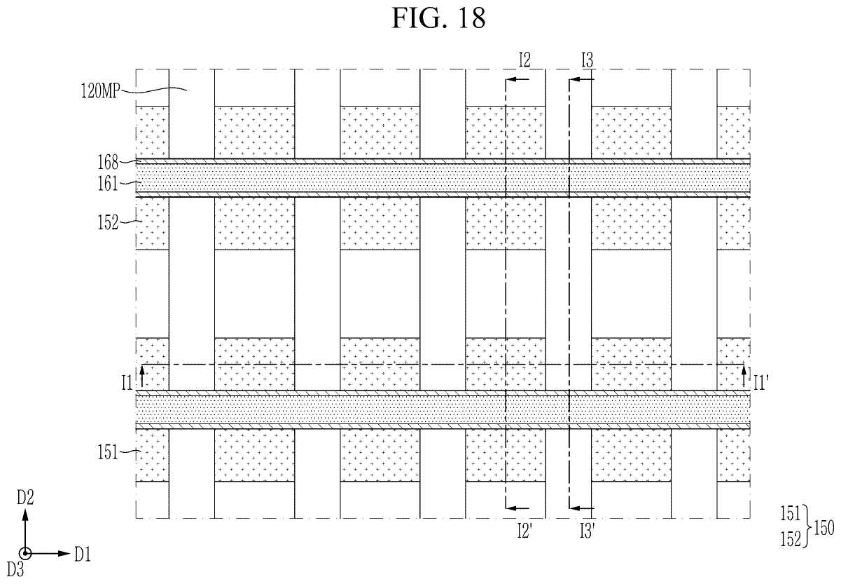

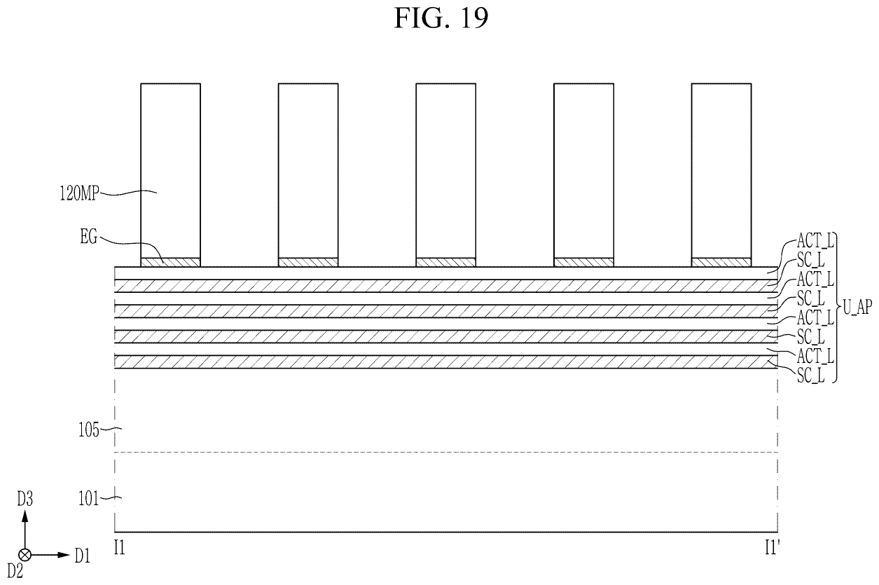

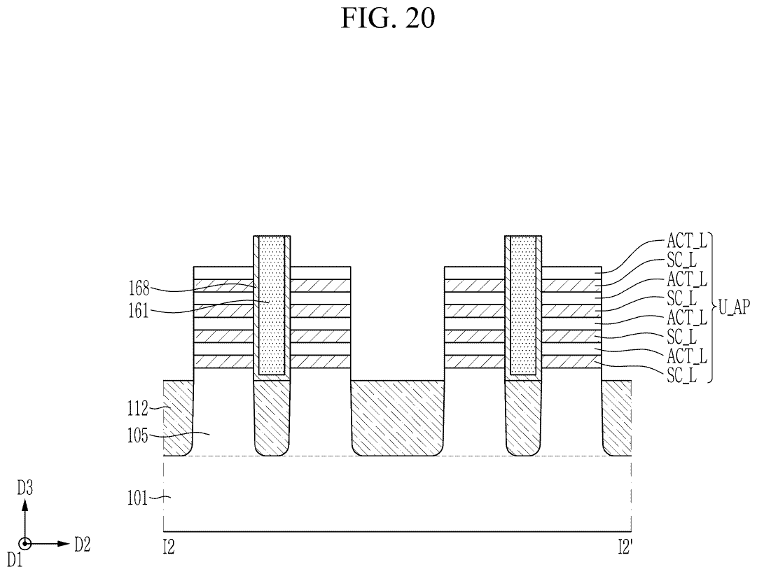

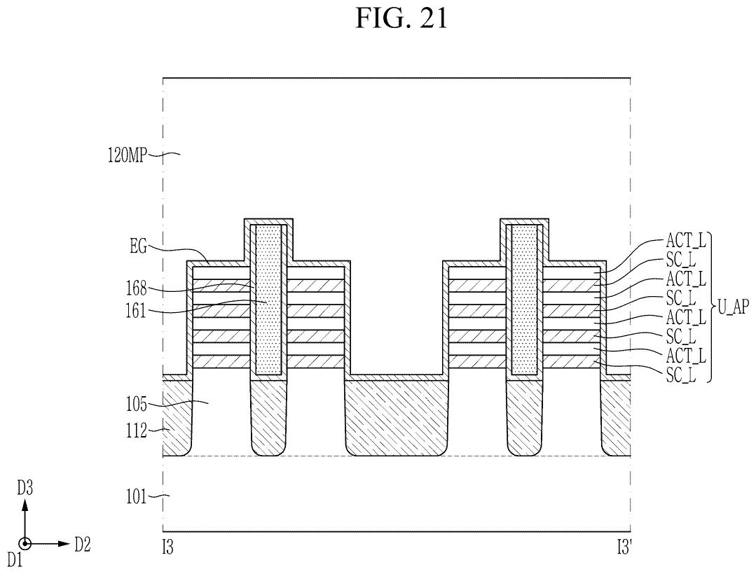

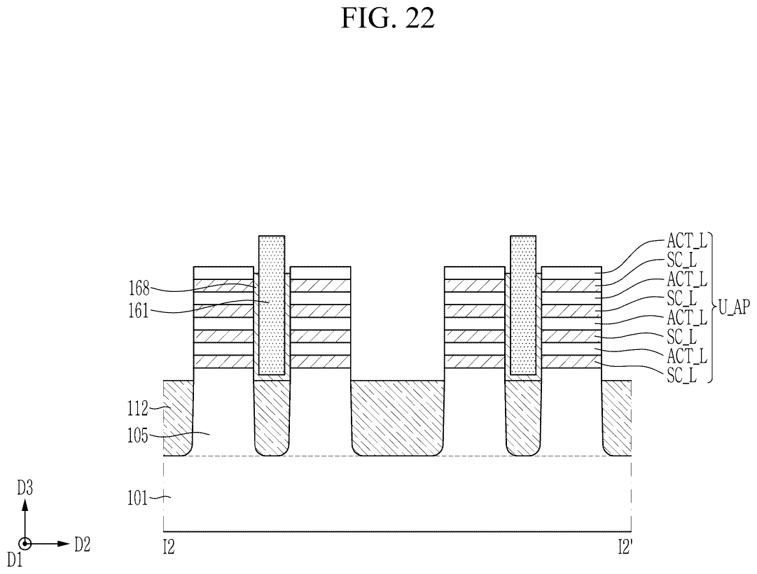

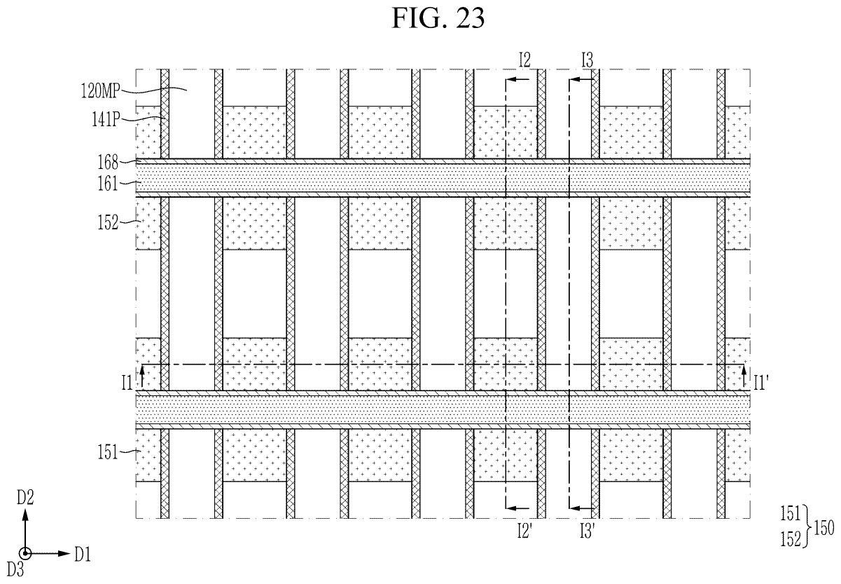

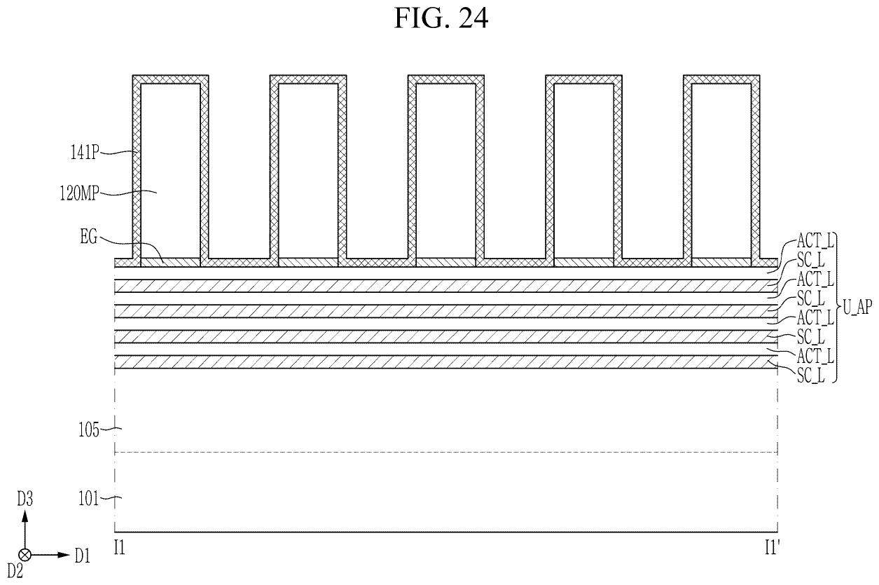

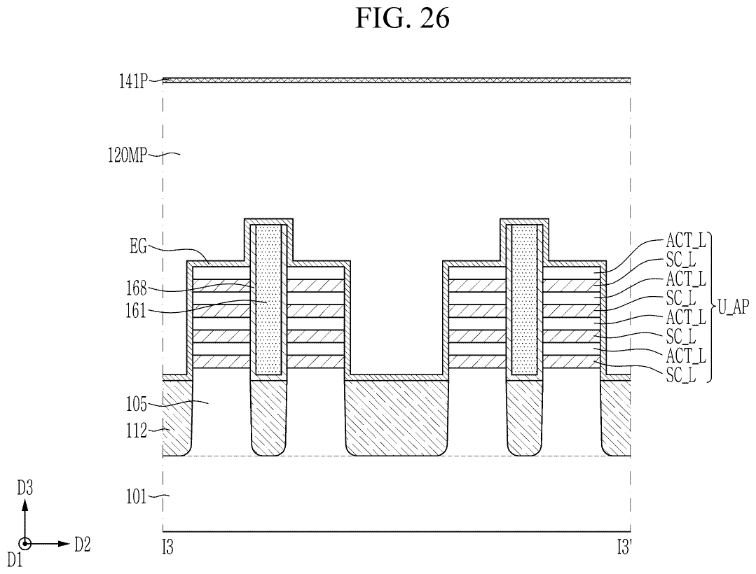

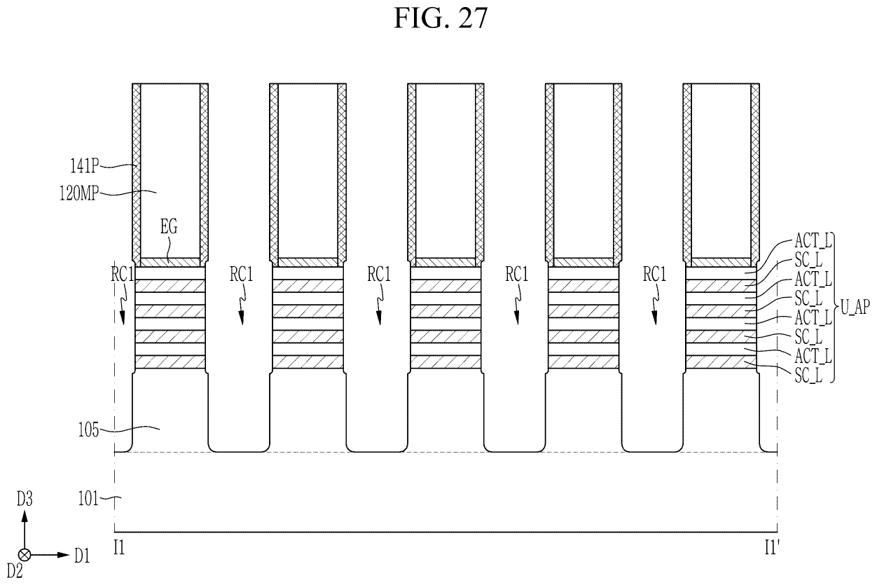

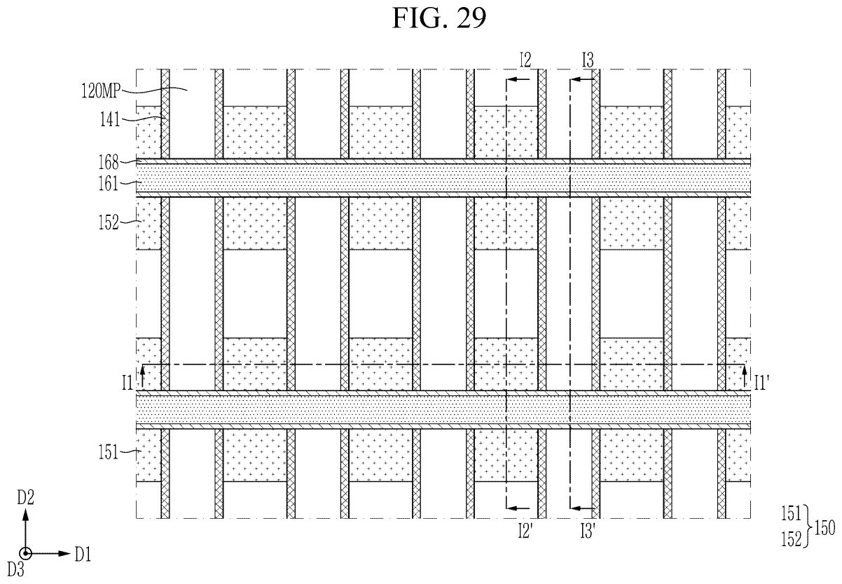

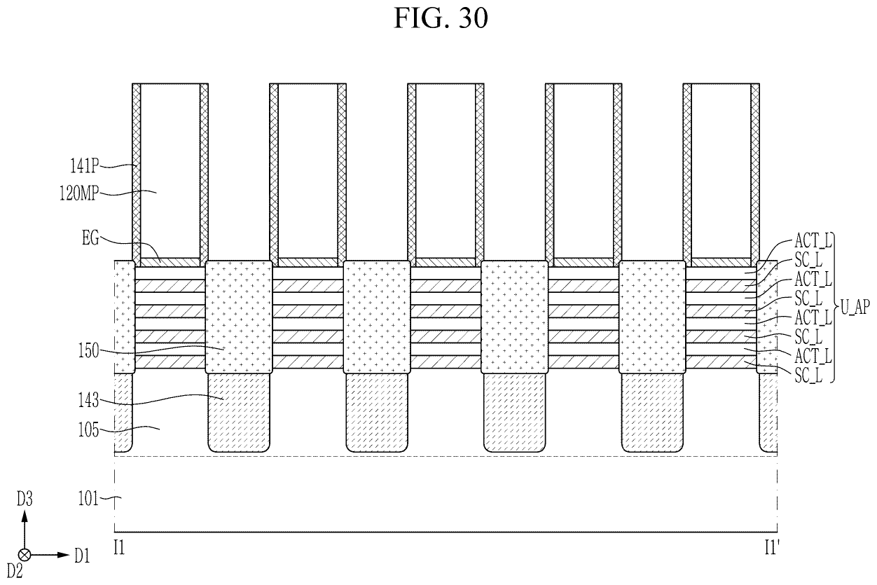

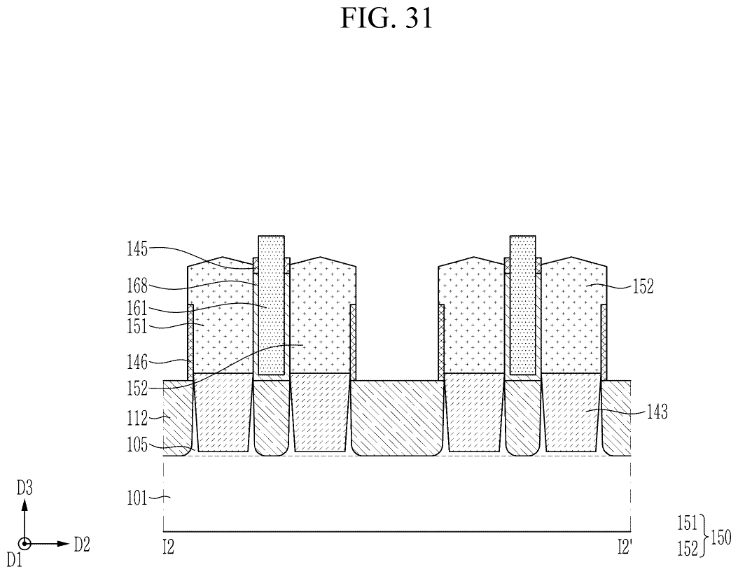

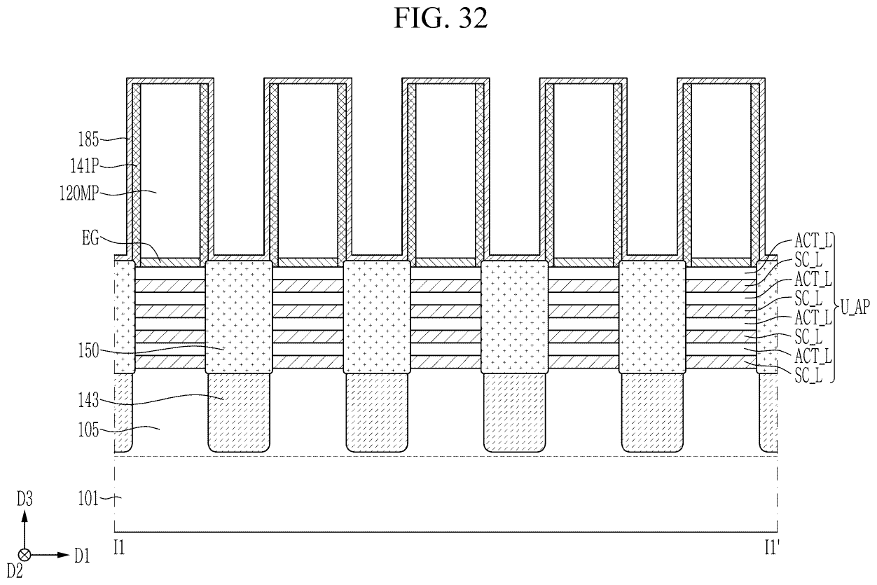

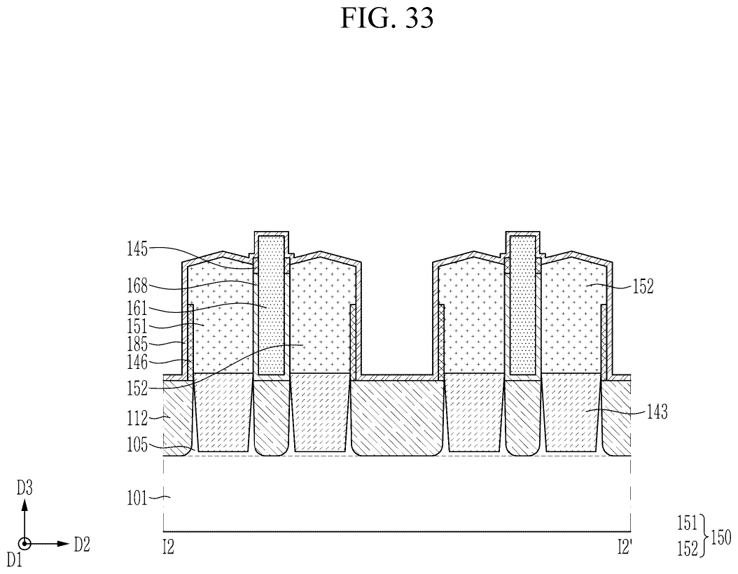

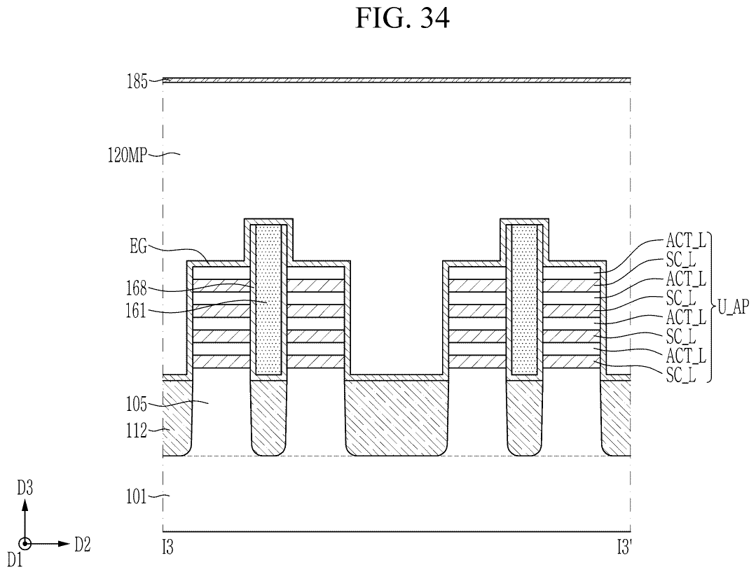

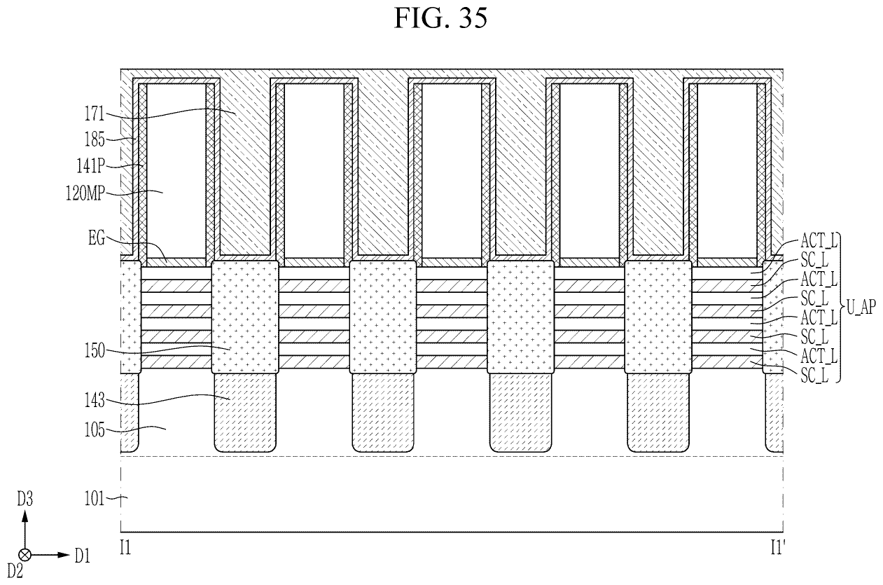

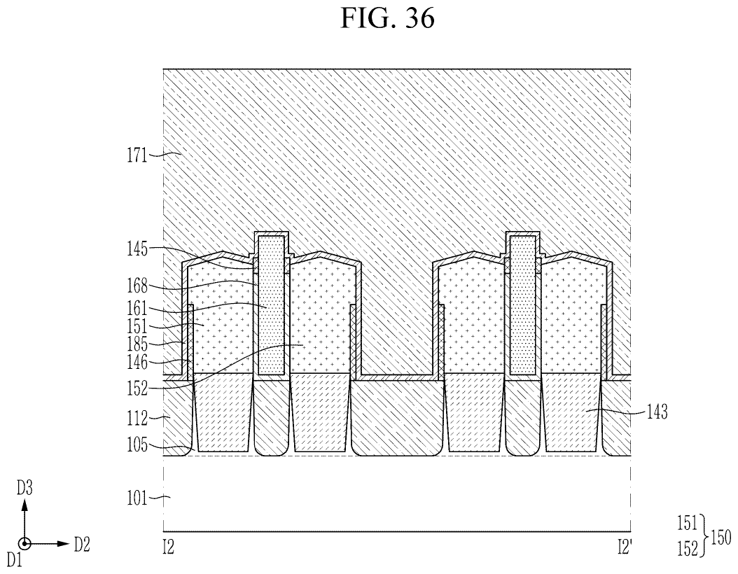

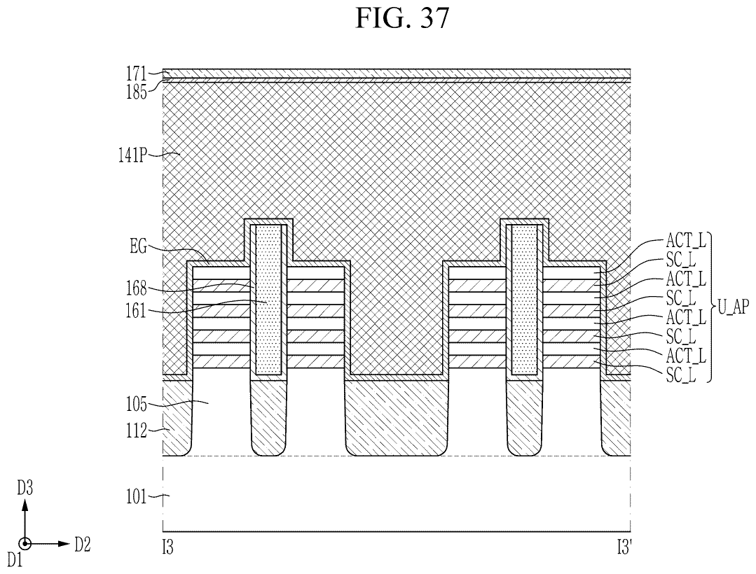

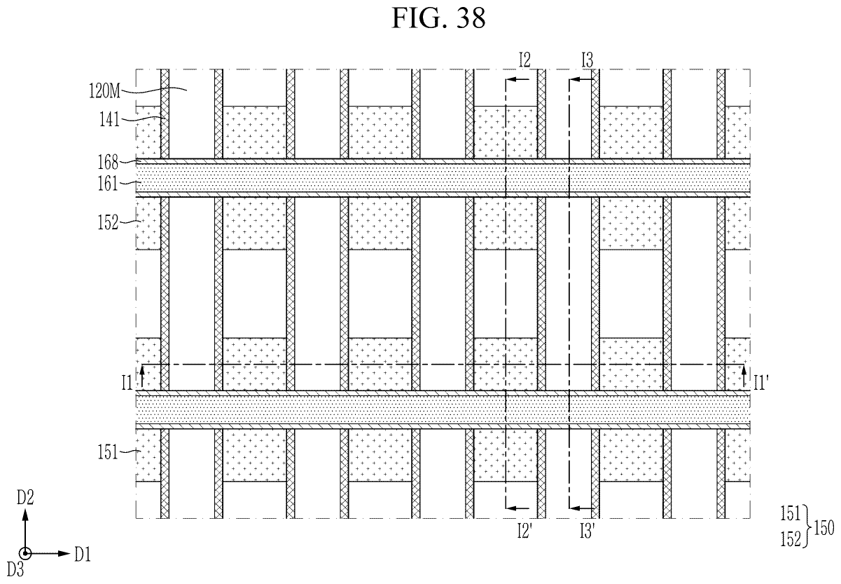

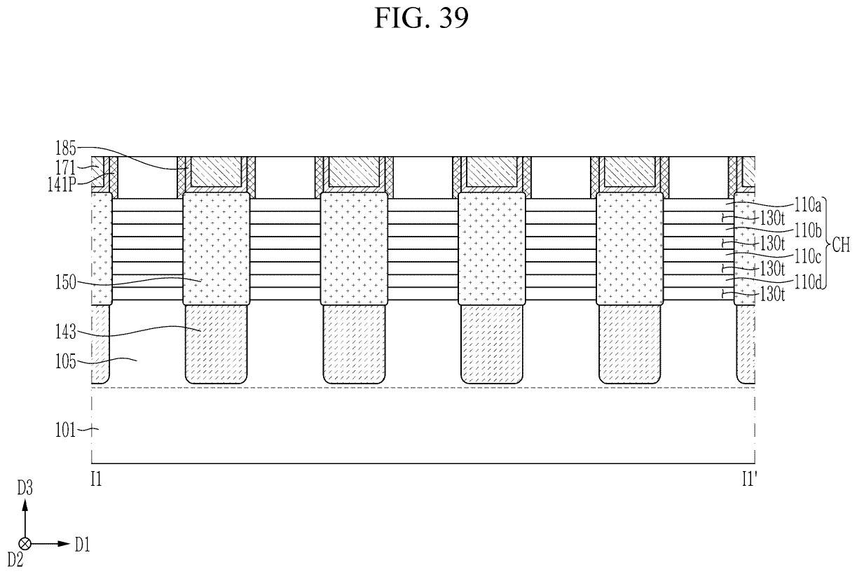

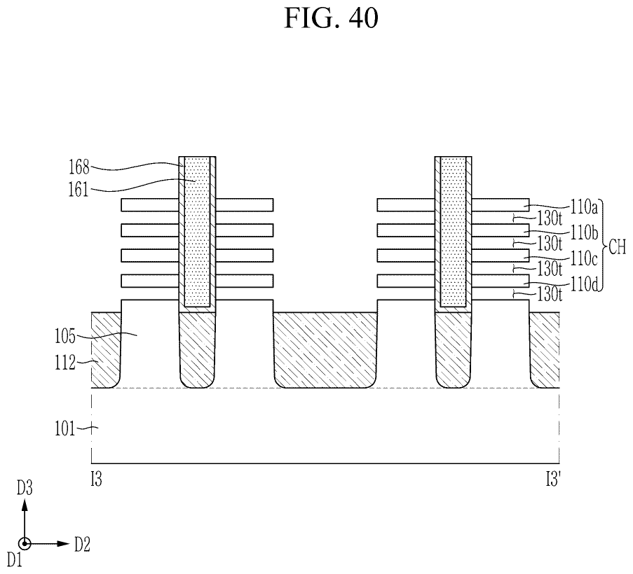

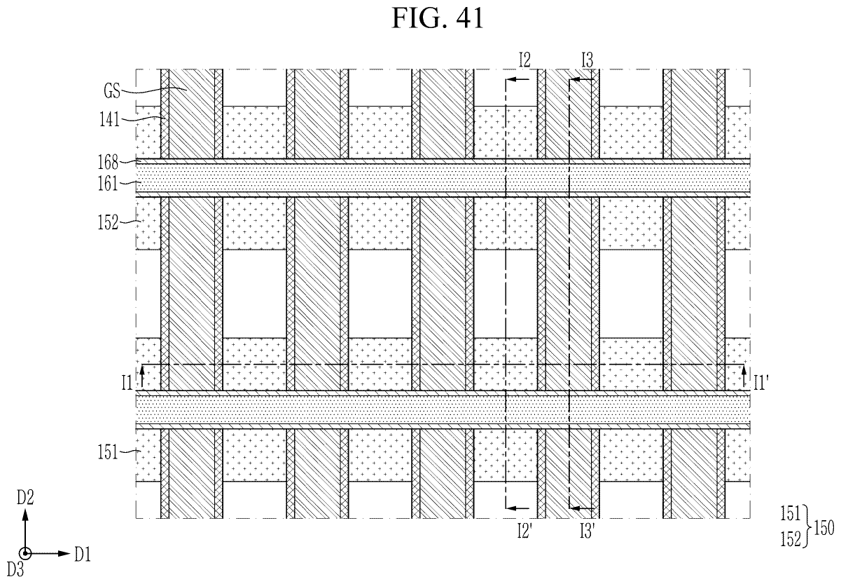

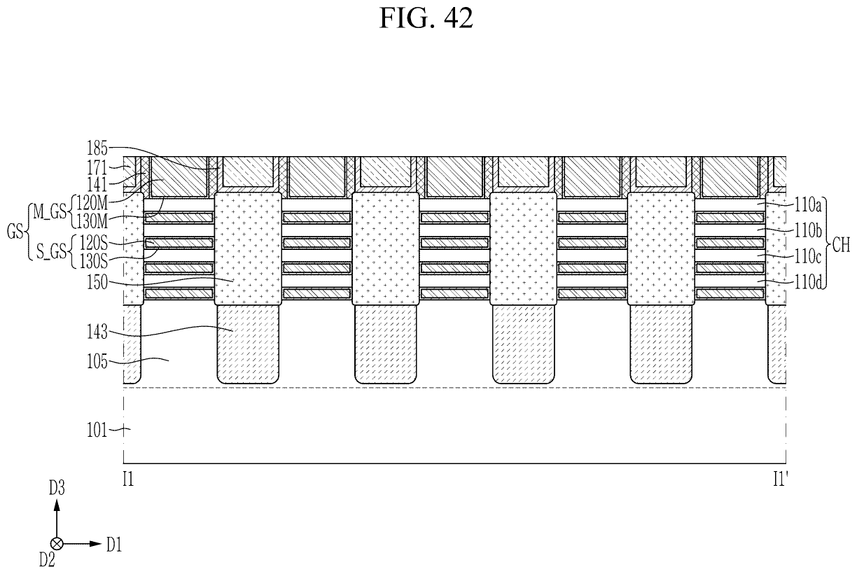

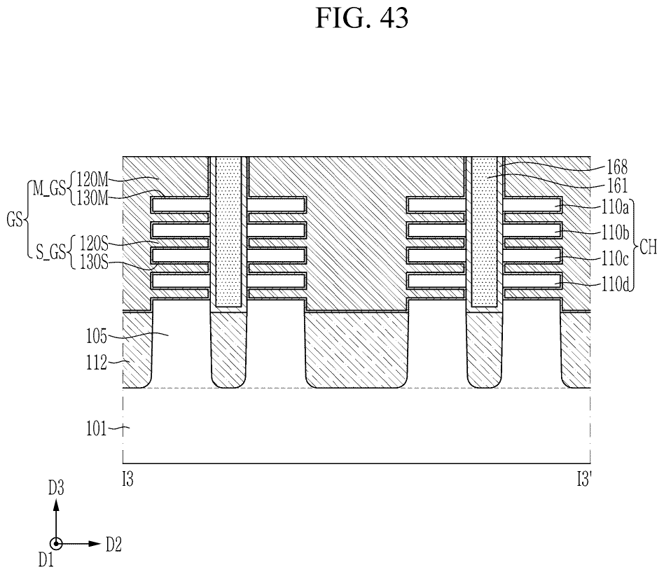

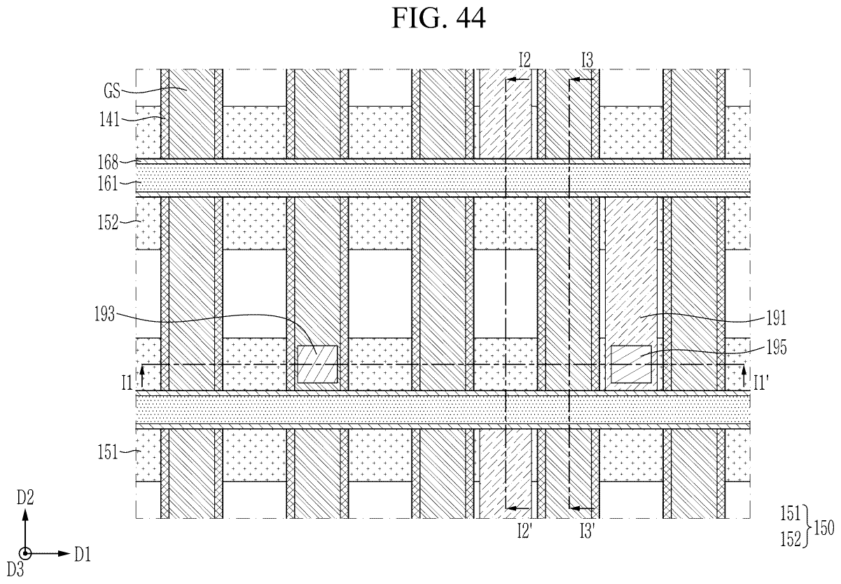

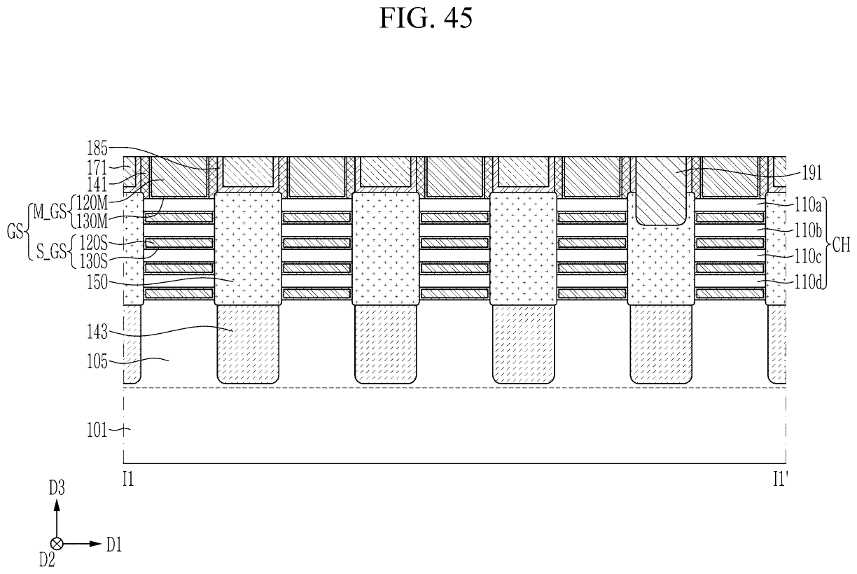

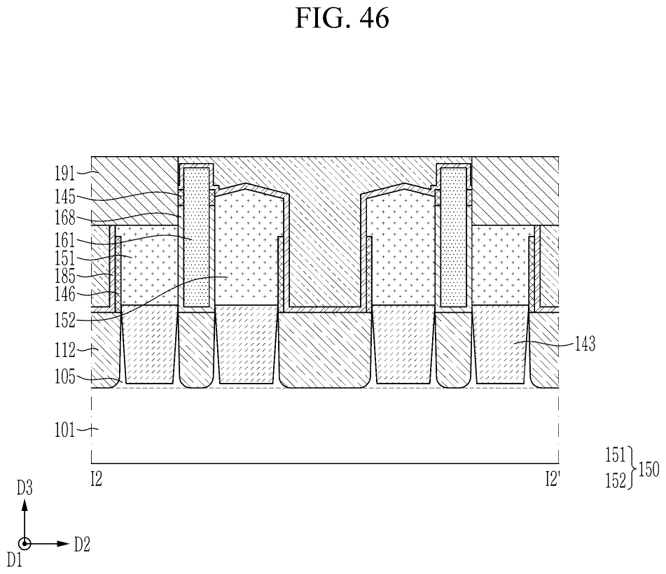

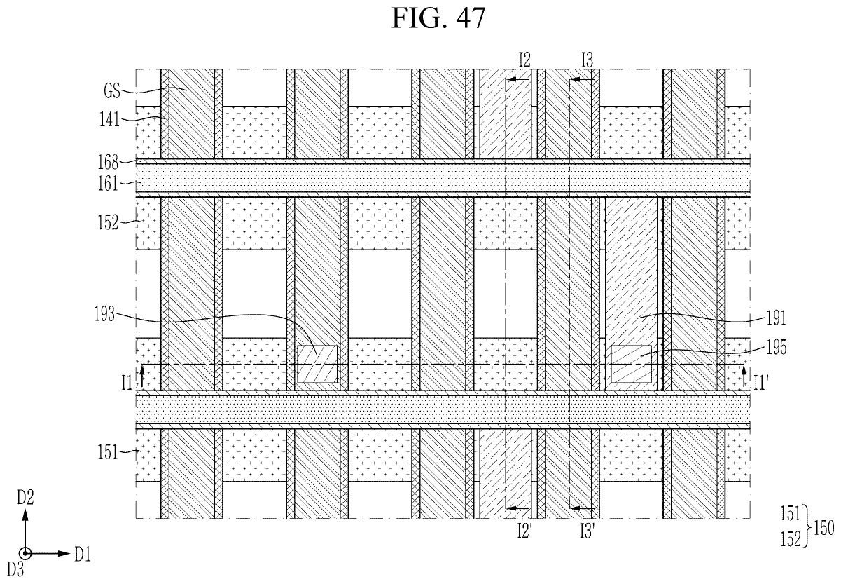

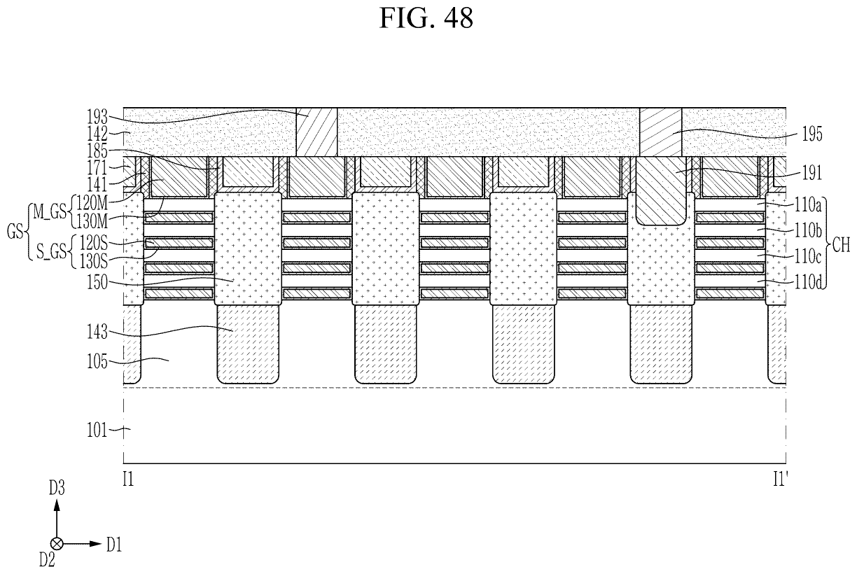

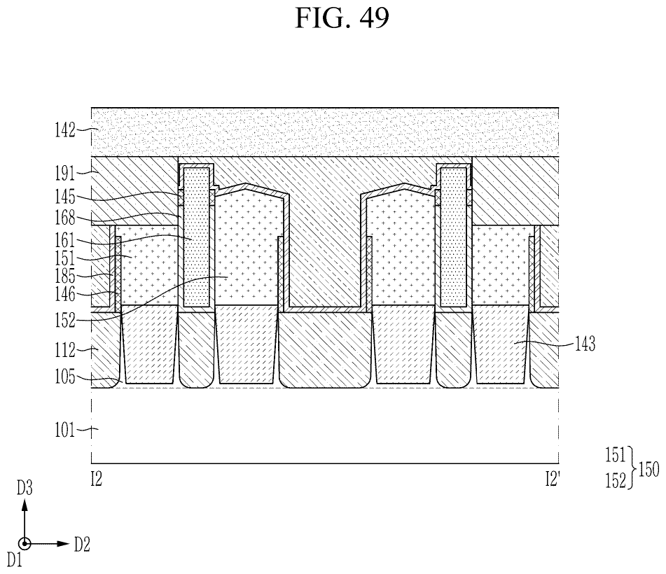

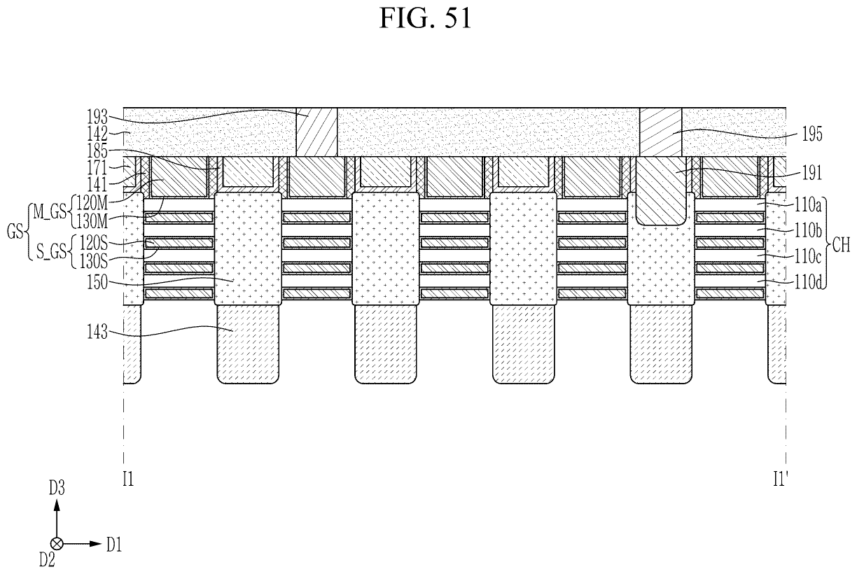

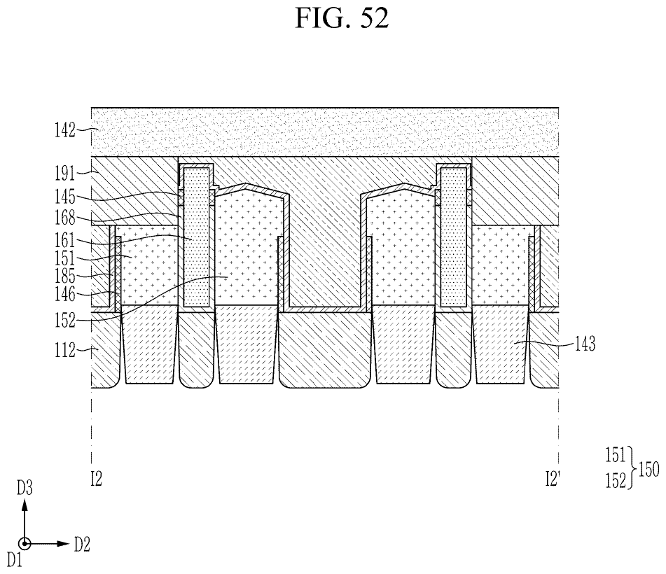

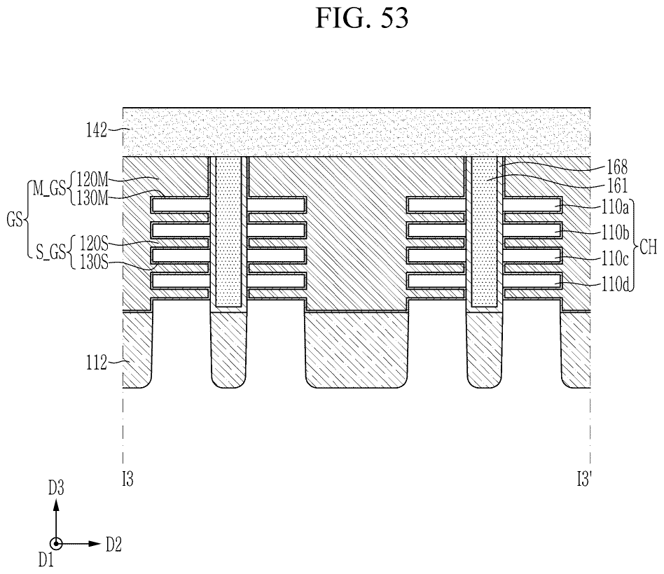

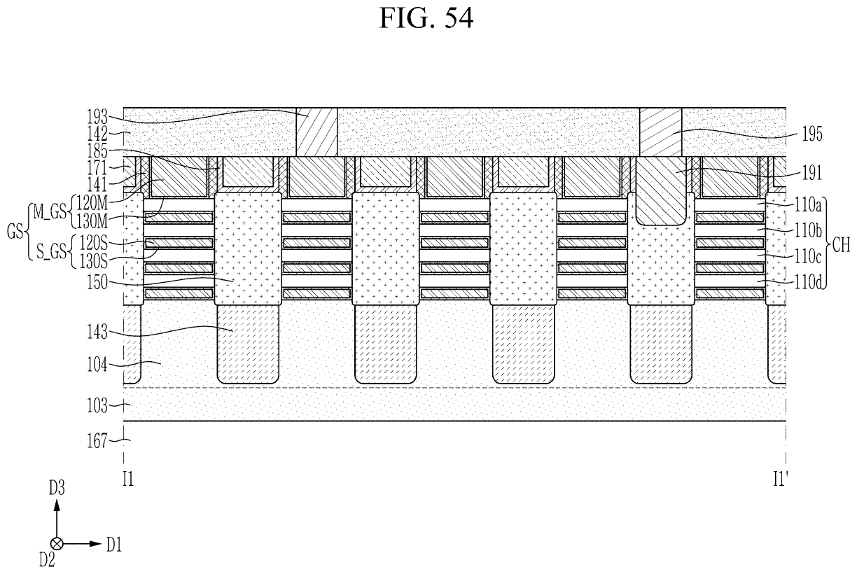

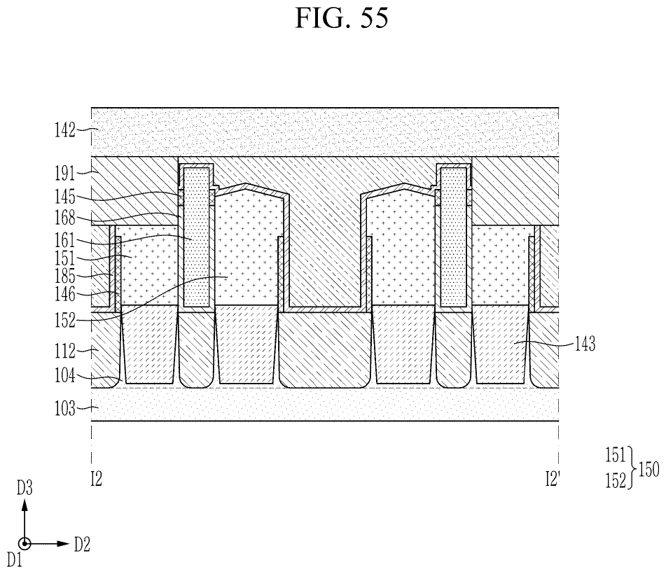

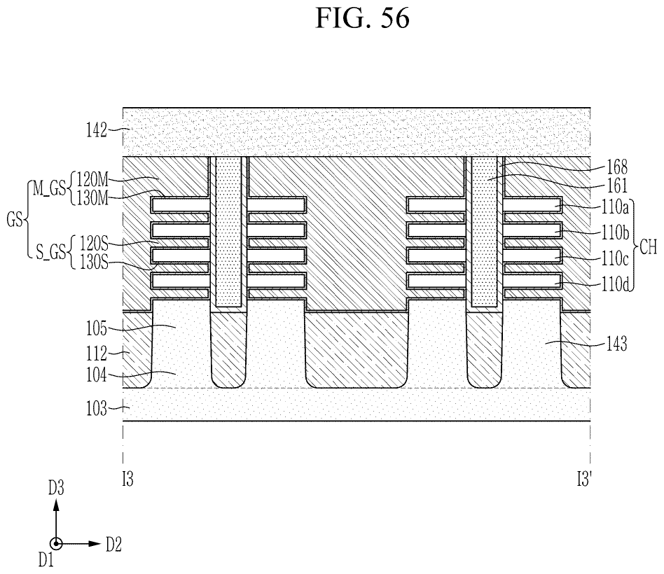

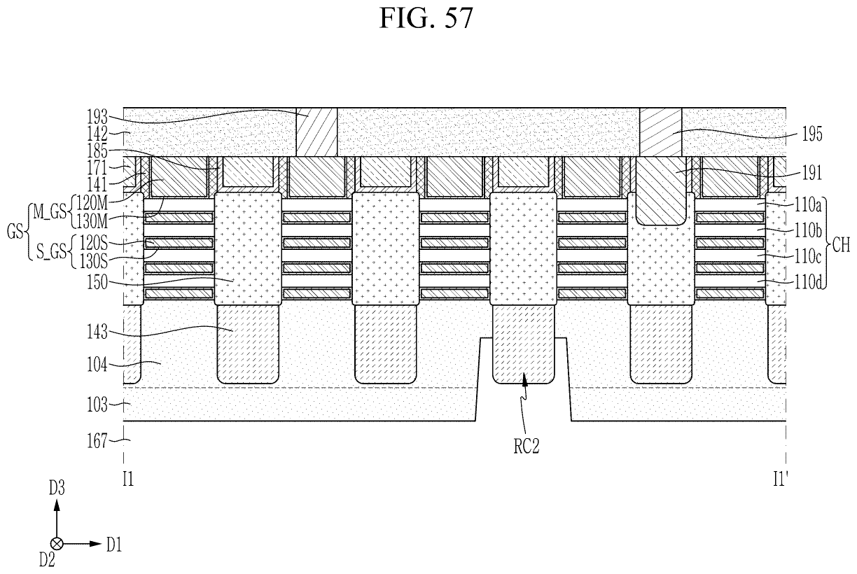

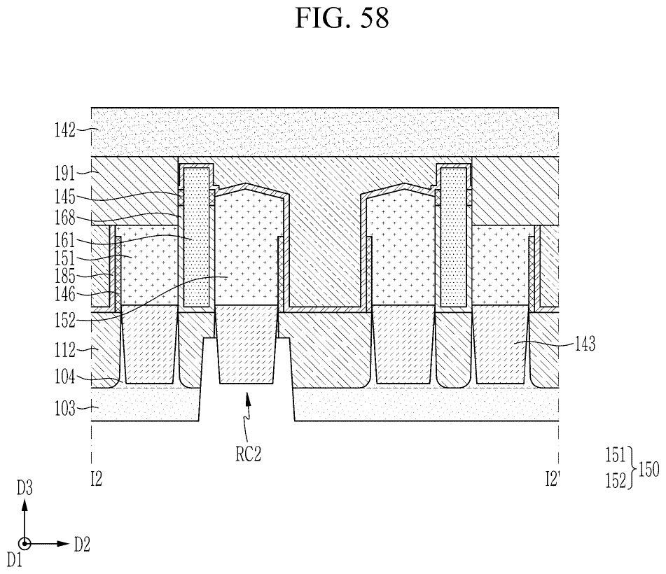

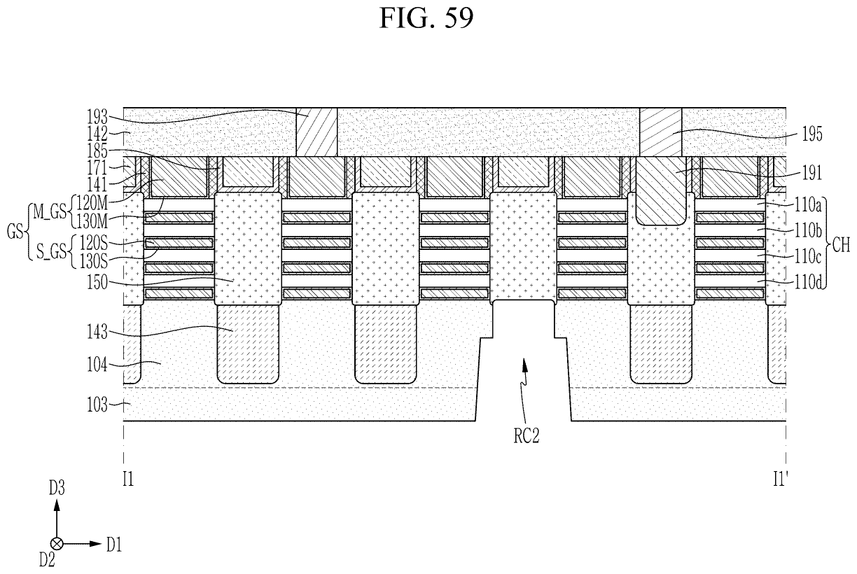

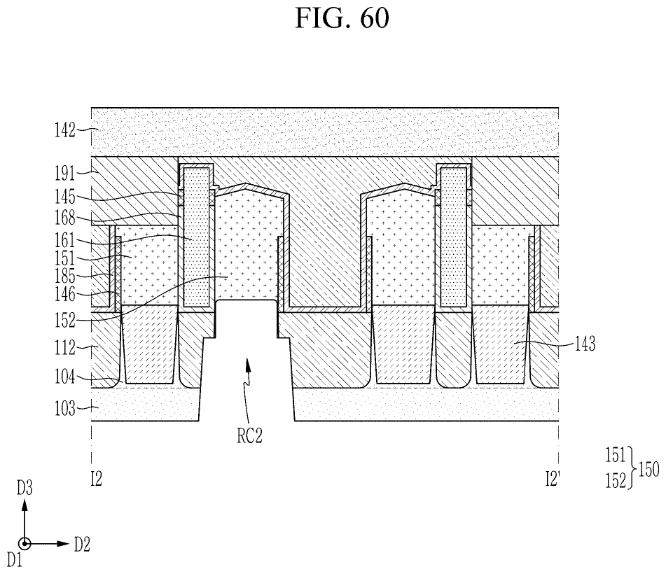

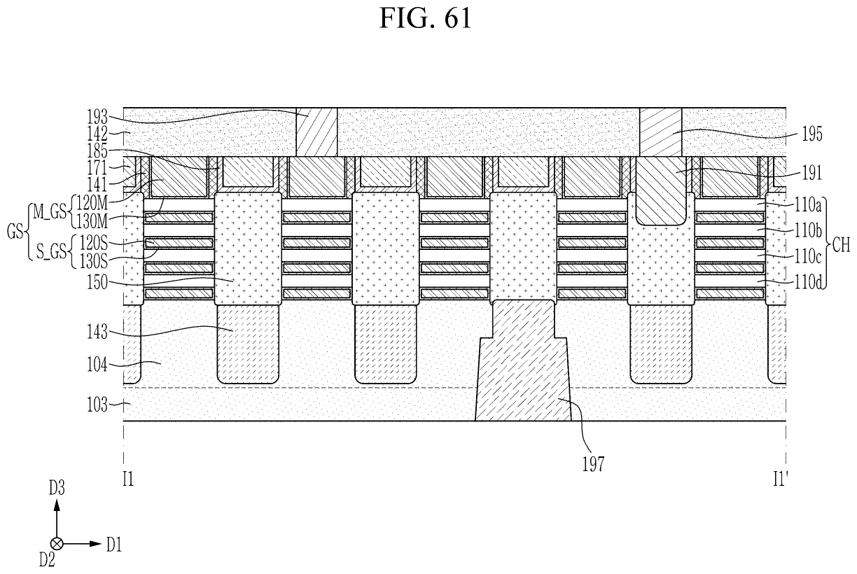

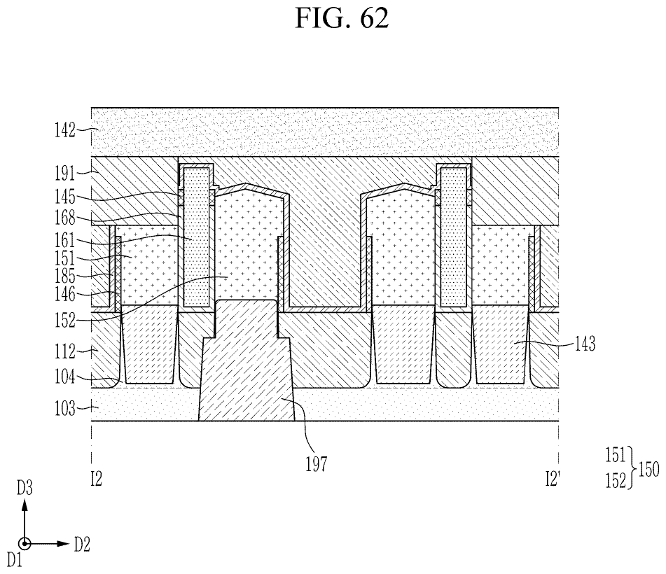

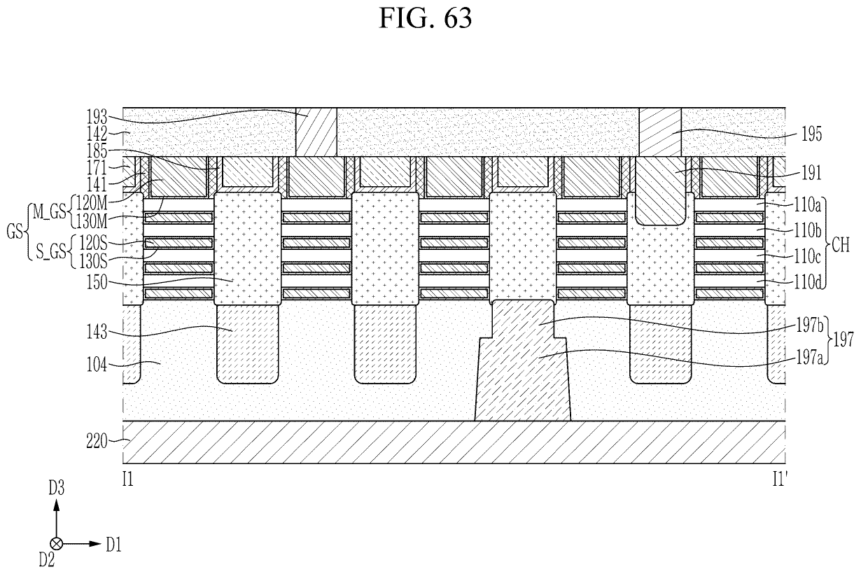

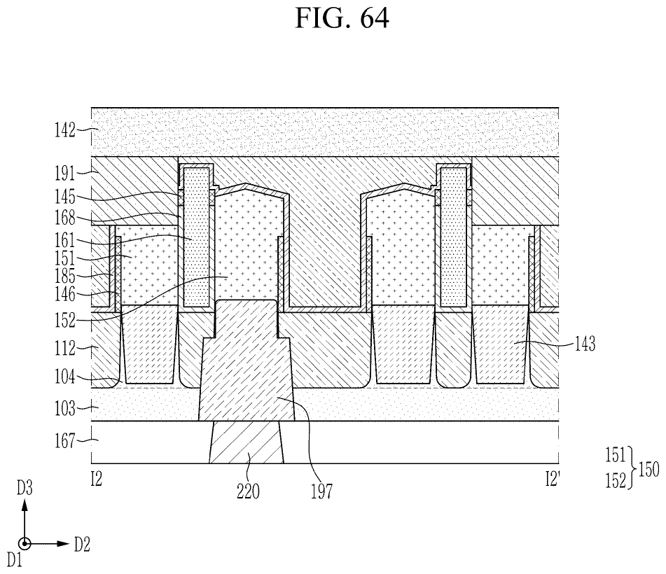

FIG. 18, FIG. 23, FIG. 29, FIG. 38, FIG. 41, FIG. 44, and FIG. 47 are plan views according to each manufacturing process step of a semiconductor device according to embodiments, and FIG. 12, FIG. 14, FIG. 16, FIG. 19, FIG. 24, FIG. 27, FIG. 30, FIG. 32, FIG. 35, FIG. 39, FIG. 42, FIG. 45, FIG. 48, FIG. 51, FIG. 54, FIG. 57, FIG. 59, FIG. 61, and FIG. 63 are cross-sectional views taken along line l1-l1′ of FIG. 1, and FIG. 13, FIG. 15, FIG. 17, FIG. 20, FIG. 22, FIG. 25, FIG. 28, FIG. 31, FIG. 33, FIG. 36, FIG. 46, FIG. 49, FIG. 52, FIG. 55, FIG. 58, FIG. 60, FIG. 62, and FIG. 64 are cross-sectional views taken along line l2-l2′ of FIG. 1, and FIG. 21, FIG. 26, FIG. 34, FIG. 37, FIG. 40, FIG. 43, FIG. 50, FIG. 53, and FIG. 56 are cross-sectional views taken along line l3-l3′ of FIG. 1.

As shown in FIG. 12 and FIG. 13, a lower pattern 105 and an upper pattern structure U_AP may be formed on a semiconductor substrate 101.

Specifically, an upper pattern structure U_AP may be formed by alternately stacking a sacrificial pattern SC_L and an active pattern ACT_L on a semiconductor substrate 101 through an epitaxial growth method, and then etching a portion of regions. To etch the portion of the sacrificial pattern SC_L and the active pattern ACT_L, a hard mask pattern HM may be formed on the upper surface of the uppermost active pattern ACT_L. Thereafter, after patterning the hard mask pattern HM, a portion of the alternately stacked sacrificial pattern SC_L and active pattern ACT_L may be etched using the hard mask pattern HM as an etch mask. At this time, a portion of the semiconductor substrate 101 may be etched to form the lower pattern 105. Alternatively, the lower pattern 105 may be grown on the semiconductor substrate 101 through an epitaxial growth method, and then formed by being etched together when the sacrificial pattern SC_L and the active pattern ACT_L are etched.

The semiconductor substrate 101 may be SOI (silicon-on-insulator) or bulk silicon. Alternatively, the semiconductor substrate 101 may be a silicon substrate, or may include other materials, for example, silicon germanium (SiGe), silicon germanium on insulator (SGOI), indium antimonide, lead telluride compounds, indium arsenide, indium phosphide, gallium arsenide, or gallium antimonide, but is not limited thereto. In embodiments, the semiconductor substrate 101 may be a silicon (Si) substrate having a (110) crystal orientation.

The lower pattern 105 may include a semiconductor material such as silicon (Si) or germanium (Ge). Alternatively, the lower patterns 105 may include compound semiconductors. For example, the lower patterns 105 may include a group IV-IV compound semiconductor or a group III-V compound semiconductor. The group IV-IV compound semiconductor may be, for example, a binary compound or a ternary compound containing carbon (C), silicon (Si), germanium (Ge), tin (Sn), or a combination thereof. The III-V group compound semiconductor may be, for example, a binary compound, ternary compound, or quaternary compound formed by combining group III elements such as aluminum (Al), gallium (Ga), indium (In), or a combination thereof, with group V elements such as phosphorus (P), arsenic (As), antimony (Sb), or a combination thereof. The sacrificial pattern SC_L may include silicon germanium (SiGe). The active pattern ACT_L may include silicon (Si).

Next, as illustrated in FIG. 14 and FIG. 15, after forming a isolation layer 112 covering the upper surface of the semiconductor substrate 101 and at least a portion of the side surface of the lower pattern 105, an insulating liner material layer 168P and a barrier wall material layer 161P covering the upper pattern structure U_AP and the hard mask pattern HM may be formed.

The isolation layer 112 may be formed by first depositing an insulating material on the semiconductor substrate 101, the lower pattern 105, and the upper pattern structure U_AP, and then etching a portion of the insulating material. Unlike what is shown, the isolation layer 112 may be formed to cover a portion of the side surface of the upper pattern structure U_AP. Next, an insulating liner material layer 168P may be formed on the upper surface of the isolation layer 112, the side surface of the upper pattern structure U_AP, and the upper surface and side surface of the hard mask pattern HM. An insulating liner material layer 168P may be conformally formed on the upper surface of the isolation layer 112, the side surface of the upper pattern structure U_AP, and the upper surface and side surface of the hard mask pattern HM. After this, an insulating material may be deposited on the insulating liner material layer 168P to form a barrier wall material layer 161P.

Next, as shown in FIG. 16 and FIG. 17, the barrier wall 161 and the insulating liner 168 surrounding it may be formed by etching the remaining portions of the barrier wall material layer 161P and the insulating liner material layer 168P, except for the portions located between two adjacent upper pattern structures U_AP.

First, a portion of the barrier wall material layer 161P, which was deposited in the previous step, may be etched by an etch back process. At this time, a wet etching process may be performed, but is not limited thereto. Due to the loading effect, the barrier wall material layer 161P located in the remaining regions may be etched faster compared to the barrier wall material layer 161P located between adjacent upper pattern structures U_AP. For example, if the gap between two adjacent patterns is narrow, the etchant or etch gas may not easily penetrate between the two adjacent patterns. As a result, materials deposited over a wider region may be etched faster than materials located between the two adjacent patterns. In embodiments, as shown in FIG. 17, the portion of the barrier wall material layer 161P located between two adjacent upper pattern structures U_AP may be etched later than the remaining portions. Accordingly, even after the barrier wall material layer 161P is completely removed from the remaining region, the portion of the barrier wall material layer 161P located between adjacent upper pattern structures U_AP may remain to form a barrier wall 161.

Next, by an etch-back process, the remaining portions of the insulating liner material layer 168P, excluding the portions located on the lower surface and side surface of the barrier wall 161, may be etched. In this case as well, due to the loading effect, the portion of the insulating liner material layer 168P located between two adjacent upper pattern structures U_AP may remain unetched, forming the insulating liner 168.

Next, as illustrated in FIG. 18, FIG. 19, FIG. 20, and FIG. 21, a preliminary gate insulating layer EG and a preliminary gate electrode 120MP may be formed on the upper pattern structure U_AP, the barrier wall 161, and the insulating liner 168. The preliminary gate insulating layer EG may include silicon oxide (SiO₂), but is not limited thereto. The preliminary gate electrode 120MP may include polysilicon, but is not limited thereto.

Next, as shown in FIG. 22, a process of trimming a portion of the insulating liner 168 surrounding the upper surface and side surfaces of the barrier wall 161 may be performed.

In embodiments, the process of removing a portion of the insulating liner 168 may be performed using an etchant (or etching gas) having a higher etch selectivity for the insulating liner 168 compared to the barrier wall 161. In embodiments, the process of removing the insulating liner 168 may be performed until the portion of the insulating liner 168 covering the upper surface and side surface of the portion of the barrier wall 161 that protrudes further in the third direction D3 than the upper surface of the upper pattern structure U_AP among the entire region of the barrier wall 161 is completely removed. In embodiments, the process of removing a portion of the insulating liner 168 may be performed until the upper surface of the portion of the insulating liner 168 located on the side surface of the barrier wall 161 is at the same level as or a lower level than that of the upper surface of the uppermost active pattern ACT_L among the plurality of active patterns ACT_L.

In embodiments, a portion of the insulating liner 168 located in an area overlapping the preliminary gate electrode 120MP in the third direction D3 among the entire region of the insulating liner 168 may not be removed.

Next, a preliminary gate spacer 141P may be formed on the side surface of the preliminary gate electrode 120MP. In embodiments, the preliminary gate spacer 141P may be formed by depositing an insulating material over the entire upper surface of the semiconductor device, and then etching at least a portion of the insulating material located in the remaining regions, excluding the region on the side surface of the preliminary gate electrode 120MP.

First, as shown in FIG. 23, FIG. 24, FIG. 25, and FIG. 26, a preliminary gate spacer 141P covering the upper pattern structure U_AP, the barrier wall 161, the insulating liner 168, and the preliminary gate electrode 120MP may be formed. The preliminary gate spacer 141P may cover the entire upper surface and side surface of the preliminary gate electrode 120MP, the side surface of the preliminary gate insulating layer EG, and the upper surface and side surface of the upper pattern structure U_AP. In embodiments, the preliminary gate spacer 141P may also be formed on the upper surface of the insulating liner 168 on the side surface of the barrier wall 161. In embodiments, as described with reference to FIG. 22, the preliminary gate spacer 141P may also be formed on a portion of the upper surface and a portion of the side surface of the barrier wall 161, which are exposed due to the removal of a portion of the insulating liner 168.

Unlike embodiments, if the portion of the insulating liner 168 is not removed, two insulating layers 168, 141P may be formed on the side surface of the portion of the barrier wall 161 that protrudes in the third direction D3 more than the upper surface of the upper pattern structure U_AP. In this case, the preliminary gate spacer 141P formed on the side surface of the portion of the barrier wall 161 that protrudes beyond the upper surface of the upper pattern structure U_AP may cover a portion of the region overlapping the upper pattern structure U_AP in the third direction D3. If this occurs, during a subsequent process of forming a first recess RC1 (refer to FIG. 28), a portion of the active pattern ACT_L and the sacrificial pattern SC_L may not be completely removed due to a shadowing effect caused by the thickly formed preliminary gate spacer 141P on the upper surface of the portion of the upper pattern structure U_AP adjacent to the side surface of the barrier wall 161.

In embodiments, by removing a portion of the insulating liner 168 located on the side surface of the barrier wall 161 prior to the process of forming the preliminary gate spacer 141P, the shadowing effect described above may be prevented, thereby improving the reliability of the semiconductor device.

Next, as illustrated in FIGS. 27 and 28, a portion of the sacrificial patterns SC_Land active patterns ACT_L alternately stacked along the third direction D3 may be etched to form a first recess RC1. The process of forming the first recess RC1 may be performed by an anisotropic etching process. At this time, the preliminary gate electrode 120MP may be used as an etching mask.

First, a portion of the preliminary gate spacer 141P may be etched by an anisotropic etching process. In this case, a portion of the preliminary gate spacer 141P on the upper surface of the upper pattern structure U_AP and on the upper surface and side surfaces of the barrier wall 161 may be etched. At this time, a portion of the preliminary gate spacer 141P that is not completely etched and remains on the upper surface of the insulating liner 168 may form a first insulating pattern 145. At this time, a portion of the preliminary gate spacer 141P that is not completely etched and remains on one side surface of the upper pattern structure U_AP may form a second insulating pattern 146.

Next, the first recess RC1 may be formed by etching the upper surface of the upper pattern structure U_AP exposed to the outside in a third direction D3. In the process of forming the first recess RC1, not only the active patterns ACT_L and the sacrificial patterns SC_L, but also a portion of region of the lower pattern 105 may be etched. In embodiments, the process of etching the first recess RC1 may be performed until the bottom surface of the first recess RC1 is adjacent to the lower surface of the lower pattern 105.

Next, as illustrated in FIG. 29, FIG. 30, and FIG. 31, a dummy semiconductor pattern 143 and a source/drain pattern 150 may be formed within the first recess RC1. The dummy semiconductor pattern 143 may be formed by a selective epitaxial growth process using the lower pattern 105 located on the bottom surface and side surface of the first recess RC1 as a seed. Accordingly, the side and bottom surfaces of the dummy semiconductor pattern 143 may be in contact with the lower pattern 105. The source/drain pattern 150 may be formed by a selective epitaxial growth process using the upper surface of the dummy semiconductor pattern 143 and a plurality of active patterns ACT_L as seeds. The source/drain pattern 150 may be formed within the first recess RC1. The side surface and bottom surface of the source/drain pattern 150 may each be in contact with the side surface of a plurality of active patterns ACT_L and the upper surface of the dummy semiconductor pattern 143.

In embodiments, the source/drain patterns 150 may be prepredominantly grown in a vertical direction (e.g., a third direction D3) rather than growing in a horizontal direction (e.g., a first direction D1 or a second direction D2). In embodiments, since the source/drain patterns 150 are prepredominantly grown in the vertical direction, two source/drain patterns 150 adjacent to opposite sides of the barrier wall 161 may not come into contact with one another while growing, and thus the reliability of the semiconductor device may be improved.

In embodiments, the source/drain pattern 150 and the dummy semiconductor pattern 143 may include silicon germanium (SiGe). In embodiments, the silicon germanium (SiGe) included in the dummy semiconductor pattern 143 may have a higher germanium (Ge) concentration compared to the source/drain pattern 150.

Next, as illustrated in FIG. 32, FIG. 33, and FIG. 34, an etch stop layer 185 covering the preliminary gate electrode 120MP, the preliminary gate spacer 141P, and the source/drain pattern 150 may be formed. The etch stop layer 185 may also cover the upper surface and a portion of side surface of the barrier wall 161 protruding above the upper surface of the source/drain pattern 150, and the upper surface and at least a portion of the side surface of the first insulating pattern 145.

In embodiments, the etch stop layer 185 may be conformally formed on the upper surface of the preliminary gate electrode 120MP, the side surface of the preliminary gate spacer 141P, the upper surface and side surface of the source/drain pattern 150, a portion of the upper surface and side surface of the barrier wall 161 protruding above the upper surface of the source/drain pattern 150, and a portion of the upper surface and side surface of the first insulating pattern 145. In embodiments, the etch stop layer 185 may also be formed on the upper surface of the isolation layer 112.

Next, as illustrated in FIG. 35, FIG. 36, and FIG. 37, an interlayer insulating layer 171 covering the source/drain pattern 150 and the isolation layer 112 may be formed. The interlayer insulating layer 171 may cover the etch stop layer 185. The interlayer dielectric layer 171 may cover an etch stop layer 185 conformally formed on the upper surface of the isolation layer 112, the upper surface and side surface of the source/drain pattern 150, the upper surface and a portion of the side surfaces of the barrier wall 161, and the upper surface and a portion of side surface of the first insulating pattern 145.

As illustrated in FIG. 38, FIG. 39, and FIG. 40, a portion of the interlayer insulating layer 171, the etch stop layer 185, the preliminary gate electrode 120MP, and the preliminary gate spacer 141P may be removed. Thereafter, the preliminary gate insulating layer EG and the sacrificial patterns SC_L may be removed to form a plurality of channel patterns 110a, 110b, 110c, 110d and gate trenches 130t located between the plurality of channel patterns 110a, 110b, 110c, 110d.

Next, as shown in FIG. 41, FIG. 42, and FIG. 43, a sub-gate insulating layer 130S and a main gate insulating layer 130M may be formed within a gate trench 130t, and sub-gate electrodes 120S and main gate electrodes 120M may be formed sequentially. The sub-gate insulating layer 130S and the main gate insulating layer 130M may be formed simultaneously in the same process. The sub-gate electrode 120S and the main gate electrode 120M may be formed simultaneously in the same process.

As illustrated in FIG. 44, FIG. 45, and FIG. 46, a first upper contact electrode 191 may be formed on at least one of the source/drain patterns 150. First, through a photolithography and etching process, a portion of the interlayer insulating layer 171 overlapping the source/drain pattern 150 in the third direction D3 is etched, and then, through an anisotropic etching process, a recess extending to a predetermined depth may be formed in the upper region of the source/drain pattern 150. Next, a recess formed on the upper portion of the source/drain pattern 150 may be filled with a conductive material to form a first upper contact electrode 191. Although not clearly shown in FIG. 45 and FIG. 46, a silicide layer may be further located at the interface where the first upper contact electrode 191 contacts the source/drain pattern 150.

Next, as shown in FIG. 47, FIG. 48, FIG. 49, and FIG. 50, a capping layer 142, and a second upper contact electrode 193 and an upper contact via 195 respectively connected to the gate structure GS and the upper contact electrode 191 through the capping layer 142 may be formed. First, a capping layer 142 may be formed that entirely covers the upper surface of the gate structure GS, the interlayer insulating layer 171, the upper contact electrode 191, and the barrier wall 161. Next, a portion of the capping layer 142 that respectively overlaps the gate structure GS and the first upper contact electrode 191 in the third direction D3 may be removed by a photolithography and etching process. Thereafter, the removed region may be filled with a conductive material to form a second upper contact electrode 193 and an upper contact via 195. After forming the second upper contact electrode 193 and the upper contact via 195, a chemical mechanical polishing process may be additionally performed.

As shown in FIG. 51, FIG. 52, and FIG. 53, the semiconductor substrate 101 and the lower pattern 105 may be removed. To remove the semiconductor substrate 101 and the lower pattern 105, at least one of a grinding process, a chemical mechanical polishing process, and a wet etching process may be performed. In embodiments, the semiconductor substrate 101 and the lower pattern 105 may be completely etched using an etchant (or etching gas, etc.) having a higher etching selectivity compared to the isolation layer 112, the insulating liner 168, and the dummy semiconductor pattern 143 for the semiconductor substrate 101 and the lower pattern 105.

As shown in FIG. 54, FIG. 55, and FIG. 56, the regions where the semiconductor substrate 101 and the lower pattern 105 were located may be filled with an insulating material to form a substrate 103 and a protruding pattern 104. The insulating material may include at least one of silicon oxide (SiO₂), silicon nitride (SiNx), and silicon oxynitride (SiON), but is not limited thereto.

As shown in FIG. 57 and FIG. 58, a portion of the entire region of the substrate 103 and the protruding pattern 104 that overlaps the source/drain pattern 150 may be removed. First, after depositing an insulating material over the entire lower surface of the substrate 103, a hard mask pattern may be formed by etching a portion of the insulating material. For this purpose, a photolithography process may be performed. At this time, a portion of the lower surface of the substrate 103 may be exposed through the hard mask pattern. The portion of the substrate 103 exposed by the hard mask pattern may include the region overlapping at least one of the source/drain patterns 150 in the third direction D3.

After this, the portion of the substrate 103 exposed through the hard mask pattern may be etched to form a second recess RC2. The process of etching the portion of the substrate 103 and the protruding pattern 104 may be performed using an etchant or an etching gas, etc., that has a higher etching selectivity for the substrate 103 and the protruding pattern 104 compared to the dummy semiconductor pattern 143. A portion of the lower region of the dummy semiconductor pattern 143 located under the source/drain pattern 150 may be exposed to the outside.

Next, as shown in FIG. 59 and FIG. 60, the dummy semiconductor pattern 143 with the lower region exposed to the outside may be etched and removed. The process of etching the dummy semiconductor pattern 143 may be performed using an etchant, etching gas, etc. that has a higher etching selectivity for the dummy semiconductor pattern 143 compared to the source/drain pattern 150.

As shown in FIG. 61 and FIG. 62, a conductive material may be deposited on the lower portion of the substrate 103 to form a lower contact electrode 197. In this case, the conductive materials formed on the lower surface of the substrate 103 may be removed through a chemical and mechanical polishing process.

As illustrated in FIG. 63 and FIG. 64, power rails 220 for supplying power to a semiconductor device according to embodiments may be formed under the substrate 103. First, a lower insulating layer 167 covering the entire lower surface area of the substrate 103 may be formed. After this, a portion of the lower insulating layer 167 may be patterned by a photolithography and etching process, and then a conductive material may be deposited to form the power rail 220.

Although embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device comprising:
a substrate;
a barrier wall on the substrate and extending in a first direction substantially perpendicular to an upper surface of the substrate;
a first channel structure and a second channel structure spaced apart from one another across the barrier wall;
a gate structure surrounding the first channel structure and the second channel structure;
a first source/drain pattern connected to one side of the first channel structure;
a second source/drain pattern connected to one side of the second channel structure and spaced apart from the first source/drain pattern across the barrier wall;
an insulating liner on at least a portion of a side surface of the barrier wall;
wherein the barrier wall includes a first region between the first channel structure and the second channel structure, and a second region between the first source/drain pattern and the second source/drain pattern; and
wherein an upper surface of the second region is located on a higher level than that of an upper surface of a portion of the insulating liner on a side surface of the second region.

2. The semiconductor device of claim 1, further comprising:
a first insulating pattern located on the insulating liner, covering a portion of a side surface of the second region,
wherein a width of the first insulating pattern in a second direction substantially perpendicular to the first direction is equal to or less than a width of a portion of the insulating liner on the side surface of the barrier wall in the second direction.

3. The semiconductor device of claim 1,
wherein the upper surface of the second region is located on a lower level than that of an upper surface of the first region.

4. The semiconductor device of claim 1,
wherein the insulating liner is on side surfaces of the first region and the second region, and
the upper surface of the portion of the insulating liner on the side surface of the second region is located on a lower level than that of an upper surface of a portion of the insulating liner on a side surface of the first region.

5. The semiconductor device of claim 4,
wherein the upper surface of the portion of the insulating liner on the side surface of the first region is located on a same level as that of the upper surface of the first region.

6. The semiconductor device of claim 1, wherein the upper surface of the second region is located on a higher level than that of an upper surface of the source/drain pattern.

7. The semiconductor device of claim 1, wherein at least one of the first source/drain pattern and the second source/drain pattern includes two side surfaces facing one another and extending in the first direction.

8. The semiconductor device of claim 7, further comprising:
a second insulating pattern extending in the first direction and covering a portion of one of the facing side surfaces of at least one of the first source/drain pattern and the second source/drain pattern,
wherein the second insulating pattern includes a same insulating material as the first insulating pattern.

9. The semiconductor device of claim 8, wherein the first source/drain pattern and the second source/drain pattern include a lower region overlapping the second insulating pattern in a second direction substantially perpendicular to the first direction, and an upper region on the lower region, and
wherein a maximum width of the upper region in the second direction is greater than a maximum width of the lower region in the second direction.

10. The semiconductor device of claim 9,
wherein a difference between the maximum width of the upper region and the maximum width of the lower region is greater than 0 and less than or equal to 10 nm.

11. The semiconductor device of claim 9,
wherein the upper region includes a portion having a width in the second direction that decreases as the portion becomes farther from the upper surface of the substrate.

12. The semiconductor device of claim 1,
wherein the barrier wall and the insulating liner include different insulating materials, and
wherein an insulating material of the barrier wall has a lower dielectric constant than that of an insulating material of the insulating liner.

13. The semiconductor device of claim 1,
wherein the barrier wall includes an insulating material having a dielectric constant lower than that of silicon dioxide (SiO₂).

14. The semiconductor device of claim 1, wherein the substrate includes silicon (Si), and an upper surface of the substrate has a (110) crystalline orientation.

15. The semiconductor device of claim 1, further comprising:
an air gap located within the barrier wall.

16. A semiconductor device comprising:
a substrate;
a barrier wall on the substrate and extending in a first direction substantially perpendicular to an upper surface of the substrate;
a first channel structure and a second channel structure spaced apart from one another across the barrier wall;
a gate structure surrounding the first channel structure and the second channel structure;
a first source/drain pattern connected to one side of the first channel structure;
a second source/drain pattern connected to one side of the second channel structure and spaced apart from the first source/drain pattern across the barrier wall;
an insulating liner on at least a portion of a side surface of the barrier wall;
wherein the first source/drain pattern and the second source/drain pattern include a lower region and an upper region on the lower region;
wherein the barrier wall includes a first region between the first channel structure and the second channel structure, and a second region between the first source/drain pattern and the second source/drain pattern; and
wherein the insulating liner is on side surfaces of the first region and the second region, and an upper surface of a portion of the insulating liner on a side surface of the second region is located on a lower level than that of an upper surface of a portion of the insulating liner on a side surface of the first region.

17. The semiconductor device of claim 16,
wherein at least one of the first source/drain pattern and the second source/drain pattern includes two side surfaces facing one another and extending in the first direction.

18. The semiconductor device of claim 16,
wherein an upper surface of the second region is located on a higher level than that of the upper surface of the portion of the insulating liner on a side surface of the second region.

19. The semiconductor device of claim 16,
wherein an upper surface of the second region is located on a lower level than that of an upper surface of the first region.

20. A semiconductor device comprising:
a substrate;
a barrier wall on the substrate and extending in a first direction substantially perpendicular to an upper surface of the substrate;
an insulating liner on at least a portion of a side surface of the barrier wall;
a first channel structure and a second channel structure spaced apart from one another across the barrier wall in a second direction substantially parallel to the upper surface of the substrate and perpendicular to the first direction;
a gate structure surrounding the first channel structure and the second channel structure;
a first source/drain pattern connected to one side of the first channel structure and having one side surface in contact with the insulating liner;
a second source/drain pattern connected to one side of the second channel structure and spaced apart from the first source/drain pattern across the barrier wall in the second direction and having one side surface in contact with the insulating liner;
a power rail located below the substrate; and
a lower contact electrode passing through the substrate in the first direction and connecting the power rail to at least one of the first source/drain pattern and the second source/drain pattern;
wherein the barrier wall includes a first region between the first channel structure and the second channel structure, and a second region between the first source/drain pattern and the second source/drain pattern; and
wherein an upper surface of the second region is located on a higher level than that of an upper surface of a portion of the insulating liner on a side surface of the second region.
